(19) United States
(12) Patent Application Publication
(10) Pub. No.: US 2026/0271785 A1
(43) Pub. Date: Sep. 10, 2026

(54) MEMORY DEVICES, FABRICATION METHODS, AND OPERATING METHODS THEREOF

(71) Applicant: Yangtze Memory Technologies Holding Co., Ltd., Wuhan (CN)

(72) Inventors: Hao Zheng, Wuhan (CN); Dongyu Fan, Wuhan (CN); Tingting Gao, Wuhan (CN); Lei Liu, Wuhan (CN); Wenxi Zhou, Wuhan (CN); Zhiliang Xia, Wuhan (CN); Zongliang Huo, Wuhan (CN)

(73) Assignee: Yangtze Memory Technologies Holding Co., Ltd., Wuhan (CN)

(21) Appl. No.: 19/338,541

(22) Filed: Sep. 24, 2025

(30) Foreign Application Priority Data
Mar. 10, 2025 (CN) 202510279437.1

(51) Int. Cl. H10W 90/00; H10B 80/00; H10D 80/30; H10W 20/00; H10W 20/20; H10W 70/60; H10W 90/20; H10W 90/26

(52) U.S. Cl. CPC H10W 90/00; H10B 80/00; H10D 80/30; H10W 20/021; H10W 20/20; H10W 70/60; H10W 70/611; H10W 90/26; H10W 90/297; H10W 90/732

(57) ABSTRACT

A memory device includes a first semiconductor chip including a first semiconductor structure and a first interconnection structure; a second semiconductor chip stacking with the first semiconductor chip along a first direction, the second semiconductor chip including a second semiconductor structure and a second interconnection structure; a first contact structure extending along the first direction in the first semiconductor chip in contact with the first interconnection structure. The first contact structure includes a first inner conductive layer and a first outer conductive layer surrounding the first inner conductive layer, and the first interconnection structure extends along a second direction perpendicular to the first direction.

### CROSS-REFERENCE TO RELATED APPLICATIONS

This application claims the benefit of priority to Chinese Application No. 202510279437.1, filed on Mar. 10, 2025, which is incorporated herein by reference in its entirety.

### BACKGROUND

The present disclosure relates to semiconductor structures, fabrication methods, and operating methods thereof, specifically to memory devices, fabrication methods of the memory, and driving methods of the memory.

Planar memory cells are scaled to smaller sizes by improving process technology, circuit design, programming algorithm, and fabrication process. However, as feature sizes of the memory cells approach a lower limit, planar process and fabrication techniques become challenging and costly. As a result, memory density for planar memory cells approaches an upper limit.

A high bandwidth memory (HBM) uses stacked memory devices or memory chips to enable effective data movement and access. While using less power in a smaller form factor, HBM devices can achieve higher bandwidth. HBM devices have been applied to high-performance graphics accelerators, network devices, high-performance data centers, artificial intelligence (AI) and machine learning (ML) training, and various supercomputers.

### SUMMARY

According to one aspect of the present disclosure, a memory device is disclosed. The memory device includes a first semiconductor chip including a first semiconductor structure and a first interconnection structure; a second semiconductor chip stacking with the first semiconductor chip along a first direction, the second semiconductor chip including a second semiconductor structure and a second interconnection structure; a first contact structure extending along the first direction in the first semiconductor chip in contact with the first interconnection structure. The first contact structure includes a first inner conductive layer and a first outer conductive layer surrounding the first inner conductive layer, and the first interconnection structure extends along a second direction perpendicular to the first direction.

In some implementations, the memory device further includes a second contact structure extending along the first direction in the first semiconductor chip and the second semiconductor chip, and the second contact structure is in contact with the second interconnection structure. The second contact structure includes a second inner conductive layer and a second outer conductive layer surrounding the second inner conductive layer.

In some implementations, the first inner conductive layer and the first outer conductive layer are arranged along the second direction, and the second inner conductive layer and the second outer conductive layer are arranged along the second direction.

In some implementations, the second contact structure extends along the first direction in contact with the second interconnection structure without contacting the first interconnection structure.

In some implementations, the first contact structure further includes a first dielectric layer disposed between the first inner conductive layer and the first outer conductive layer, and the second contact structure further includes a second dielectric layer disposed between the second inner conductive layer and the second outer conductive layer.

In some implementations, a length of the first inner conductive layer along the first direction is greater than a length of the first outer conductive layer along the first direction, and a length of the second inner conductive layer along the first direction is greater than a length of the second outer conductive layer along the first direction.

In some implementations, the first interconnection structure includes a first conductive line extending along the second direction and a second conductive line extending along the second direction, and the second interconnection structure includes a third conductive line extending along the second direction and a fourth conductive line extending along the second direction.

In some implementations, the first conductive line is parallel to the second conductive line, and the third conductive line is parallel to the fourth conductive line.

In some implementations, the first outer conductive layer is in contact with the first conductive line, the first inner conductive layer is in contact with the second conductive line, the second outer conductive layer is in contact with the third conductive line, and the second inner conductive layer is in contact with the fourth conductive line.

In some implementations, a width of the first conductive line along a third direction perpendicular to the first direction and the second direction is greater than a width of the second conductive line along the third direction, and a width of the third conductive line along the third direction is greater than a width of the fourth conductive line along the third direction.

In some implementations, the first semiconductor structure includes a memory array and a periphery circuit, and the first contact structure is coupled to the periphery circuit through the first interconnection structure.

In some implementations, the memory array includes a memory element and a capacitor, and the memory element and the capacitor are arranged along the first direction.

In some implementations, the memory device further includes a base die stacking with the first semiconductor chip and the second semiconductor chip along the first direction. The first contact structure is in contact with the base die.

In some implementations, the second semiconductor chip is stacked with the first semiconductor chip through a third dielectric layer.

In some implementations, a length of the second contact structure along the first direction is greater than a length of the first contact structure along the first direction, and a length of the second interconnection structure along the second direction is greater than a length of the first interconnection structure along the second direction.

In some implementations, a diameter of the first inner conductive layer is between 1 micrometer and 10 micrometers, and a diameter of the first outer conductive layer is between 3 micrometers and 20 micrometers.

In some implementations, the first inner conductive layer and the first outer conductive layer form a pattern of concentric circles in a plan view of the memory device.

In some implementations, the first inner conductive layer and the first outer conductive layer form a concentric column extending along the first direction.

According to another aspect of the present disclosure, a method of forming a memory device is disclosed. The method includes forming a first semiconductor chip including a first semiconductor structure and a first interconnection structure; forming a second semiconductor chip including a second semiconductor structure and a second interconnection structure; bonding the first semiconductor chip and the second semiconductor chip along a first direction; forming a first contact structure including a first inner conductive layer and a first outer conductive layer surrounding the first inner conductive layer. The first contact structure extends along the first direction in the first semiconductor chip in contact with the first interconnection structure, and the first interconnection structure extends along a second direction perpendicular to the first direction.

In some implementations, the method further includes forming a second contact structure including a second inner conductive layer and a second outer conductive layer surrounding the second inner conductive layer. The second contact structure extends along the first direction in the first semiconductor chip and the second semiconductor chip, and the second contact structure is in contact with the second interconnection structure.

In some implementations, forming the first semiconductor chip including the first semiconductor structure and the first interconnection structure includes forming the first semiconductor structure on a substrate; and forming a first conductive line and a second conductive line on the first semiconductor structure. The first conductive line and the second conductive line extend along the second direction, the second conductive line is located between the first conductive line and the first semiconductor structure along the first direction, and the first conductive line is parallel to the second conductive line.

In some implementations, forming the first contact structure including the first inner conductive layer and the first outer conductive layer surrounding the first inner conductive layer includes forming a first concentric column composed of the first inner conductive layer and the first outer conductive layer surrounding the first inner conductive layer.

In some implementations, forming the second contact structure including the second inner conductive layer and the second outer conductive layer surrounding the second inner conductive layer includes forming a second concentric column composed of the second inner conductive layer and the second outer conductive layer surrounding the second inner conductive layer.

In some implementations, forming the first contact structure including the first inner conductive layer and the first outer conductive layer surrounding the first inner conductive layer includes forming a first opening extending along the first direction in the first semiconductor chip exposing the first interconnection structure; forming the first outer conductive layer in the first opening; forming a first dielectric layer on the first outer conductive layer; and forming the first inner conductive layer on the first dielectric layer.

In some implementations, forming the first outer conductive layer in the first opening includes forming a second dielectric layer in the first opening; removing a bottom portion of the second dielectric layer to expose the first conductive line; forming the first outer conductive layer on the second dielectric layer in contact with the first conductive line; and removing a bottom portion of the first outer conductive layer and a third dielectric layer between the first conductive line and the second conductive line to expose the second conductive line.

In some implementations, forming the first dielectric layer on the first outer conductive layer includes forming the first dielectric layer in the first opening in contact with the first outer conductive layer and the second conductive line.

In some implementations, forming the first inner conductive layer on the first dielectric layer includes removing a bottom portion of the first dielectric layer to expose the second conductive line; and forming the first inner conductive layer in the first opening in contact with the second conductive line.

In some implementations, bonding the first semiconductor chip and the second semiconductor chip along the first direction includes bonding the first semiconductor chip and the second semiconductor chip through a third dielectric layer.

In some implementations, the method further includes bonding the first semiconductor chip and the second semiconductor chip to a base die; and bonding the base die and a computing die to an interposer. The first inner conductive layer and the first outer conductive layer are coupled to a first differential data driving circuit in the base die, and the second inner conductive layer and the second outer conductive layer are coupled to a second differential data driving circuit in the base die.

According to a further aspect of the present disclosure, an operating method of a memory device is disclosed. The memory device includes a first semiconductor chip, a first contact structure extending in the first semiconductor chip, the first contact structure including a first inner conductive layer and a first outer conductive layer surrounding the first inner conductive layer. The operating method includes transmitting a first data signal from the first semiconductor chip to a data receiver through the first outer conductive layer; and transmitting a second data signal from the first semiconductor chip to the data receiver through the first inner conductive layer. The first data signal and the second data signal are inverse signals.

In some implementations, the first semiconductor chip includes a first semiconductor structure and a first interconnection structure, the first interconnection structure includes a first conductive line and a second conductive line parallel to the first conductive line. Transmitting the first data signal from the first semiconductor chip to the data receiver through the first outer conductive layer includes transmitting the first data signal from the first conductive line to the data receiver through the first outer conductive layer.

In some implementations, transmitting the second data signal from the first semiconductor chip to the data receiver through the first inner conductive layer includes transmitting the second data signal from the second conductive line to the data receiver through the first inner conductive layer.

In some implementations, the operating method further includes providing a control signal, by a data butter, to a driving circuit to trigger a differential signal circuit in the driving circuit; and providing the first data signal and the second data signal by the differential signal circuit.

In some implementations, the operating method further includes receiving the first data signal and the second data signal by the data received; and differential decoding the first data signal and the second data signal to interpret a voltage difference between the first data signal and the second data signal.

### BRIEF DESCRIPTION OF THE DRAWINGS

The accompanying drawings, which are incorporated herein and form a part of the specification, illustrate implementations of the present disclosure and, together with the description, further serve to explain the present disclosure and to enable a person skilled in the pertinent art to make and use the present disclosure.

FIG. 1 illustrates a schematic view of a cross-section of a semiconductor structure, according to some implementations of the present disclosure.

FIG. 2 illustrates a schematic diagram of a memory device including peripheral circuits and an array of memory cells each having a vertical transistor, according to some aspects of the present disclosure.

FIG. 3 illustrates a schematic circuit diagram of a memory device including peripheral circuits and an array of dynamic random-access memory (DRAM) cells, according to some aspects of the present disclosure.

FIG. 4 illustrates a schematic circuit diagram of a memory device including peripheral circuits and an array of phase-change memory (PCM) cells, according to some aspects of the present disclosure.

FIG. 5 illustrates a schematic view of a cross-section of a semiconductor structure, according to some implementations of the present disclosure.

FIGS. 6A-6C illustrate schematic views of a cross-section of a semiconductor structure, according to some implementations of the present disclosure.

FIG. 7 illustrates a schematic view of a plane view of a semiconductor structure, according to some implementations of the present disclosure.

FIG. 8 illustrates a schematic view of a cross-section of a semiconductor structure showing the differential transmission path, according to some implementations of the present disclosure.

FIG. 9 illustrates a schematic view of a cross-section of a semiconductor structure showing the differential operation circuit, according to some implementations of the present disclosure.

FIGS. 10A-10B illustrate schematic views of a single-end transmission and a differential transmission operation, according to some implementations of the present disclosure.

FIGS. 11-24 illustrate cross-sectional views of a semiconductor structure at various stages of a fabrication process, according to some implementations of the present disclosure.

FIG. 25 illustrates a flowchart of a method for forming a semiconductor structure, according to some implementations of the present disclosure.

FIG. 26 illustrates a schematic view of a differential circuit, according to some implementations of the present disclosure.

FIG. 27 illustrates a block diagram of a system having a memory device, according to some implementations of the present disclosure.

FIG. 28A illustrates a diagram of a memory card having a memory device, according to some implementations of the present disclosure.

FIG. 28B illustrates a diagram of a solid-state drive (SSD) having a memory device, according to some implementations of the present disclosure.

The present disclosure will be described with reference to the accompanying drawings.

### DETAILED DESCRIPTION

Although specific configurations and arrangements are discussed, it should be understood that this is done for illustrative purposes only. As such, other configurations and arrangements can be used without departing from the scope of the present disclosure. Also, the present disclosure can also be employed in a variety of other applications. Functional and structural features as described in the present disclosures can be combined, adjusted, and modified with one another and in ways not specifically depicted in the drawings, such that these combinations, adjustments, and modifications are within the scope of the present discloses.

In general, terminology may be understood at least in part from usage in context. For example, the term “one or more” as used herein, depending at least in part upon context, may be used to describe any feature, structure, or characteristic in a singular sense or may be used to describe combinations of features, structures or characteristics in a plural sense. Similarly, terms, such as “a,” “an,” or “the,” again, may be understood to convey a singular usage or to convey a plural usage, depending at least in part upon context. In addition, the term “based on” may be understood as not necessarily intended to convey an exclusive set of factors and may, instead, allow for existence of additional factors not necessarily expressly described, again, depending at least in part on context.

It should be readily understood that the meaning of “on,” “above,” and “over” in the present disclosure should be interpreted in the broadest manner such that “on” not only means “directly on” something but also includes the meaning of “on” something with an intermediate feature or a layer therebetween, and that “above” or “over” not only means the meaning of “above” or “over” something but can also include the meaning it is “above” or “over” something with no intermediate feature or layer therebetween (i.e., directly on something).

Further, spatially relative terms, such as “beneath,” “below,” “lower,” “above,” “upper,” and the like, may be used herein for ease of description to describe one element or feature’s relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, the term “layer” refers to a material portion including a region with a thickness. A layer can extend over the entirety of an underlying or overlying structure or may have an extent less than the extent of an underlying or overlying structure. Further, a layer can be a region of a homogeneous or inhomogeneous continuous structure that has a thickness less than the thickness of the continuous structure. For example, a layer can be located between any pair of horizontal planes between, or at, a top surface and a bottom surface of the continuous structure. A layer can extend horizontally, vertically, and/or along a tapered surface. A substrate can be a layer, can include one or more layers therein, and/or can have one or more layer thereupon, thereabove, and/or therebelow. A layer can include multiple layers. For example, an interconnect layer can include one or more conductor and contact layers (in which interconnect lines and/or via contacts are formed) and one or more dielectric layers.

As used herein, the term “substrate” refers to a material onto which subsequent material layers are added. The substrate itself can be patterned. Materials added on top of the substrate can be patterned or can remain unpatterned. Furthermore, the substrate can include a wide array of semiconductor materials, such as silicon, germanium, gallium arsenide, indium phosphide, etc. Alternatively, the substrate can be made from an electrically non-conductive material, such as a glass, a plastic, or a sapphire wafer.

Implementations of the present disclosure can provide one or more of the following technical advantages and/or benefits. For example, a semiconductor device or a semiconductor structure can include multiple memory dice or memory chips stacked in the vertical direction. The multiple memory chips are bonded together using a direct bonding technology. In some implementations, the HBM may use the through silicon via (TSV) and u-bump technology to achieve die-to-wafer bonding or die-to-die bonding. However, the HBM chips have the problem of limited signal transmission frequency. In some implementations, the transmission signals in the HBM chips are transmitted through TSV for single-ended signal transmission, and the signal is easily affected by noise, resulting in limited signal frequency.

To address one or more of the aforementioned issues, the present disclosure introduces a semiconductor structure based on differential transmission. After forming the TSV openings, double-layer TSVs are formed in the openings, and the double-layer TSV can be used to perform the differential transmission operation. Therefore, higher signal transmission frequency can be achieved without increasing the number of TSVs.

The techniques can be applied to various types of semiconductor devices, volatile memory devices, such as DRAM memory devices, or non-volatile memory (NVM) devices, such as NAND flash memory, NOR flash memory, resistive random-access memory (RRAM), phase-change memory (PCM) such as phase-change random-access memory (PCRAM), spin-transfer torque (STT)-Magnetoresistive random-access memory (MRAM), among others. The techniques can also be applied to charge-trapping based memory devices, e.g., silicon-oxide-nitride-oxide-silicon (SONOS) memory devices, and floating-gate based memory devices. The techniques can be applied to three-dimensional (3D) memory devices. The techniques can be applied to various memory types, such as SLC (single-level cell) devices, MLC (multi-level cell) devices like 2-level cell devices, TLC (triple-level cell) devices, QLC (quad-level cell) devices, or PLC (penta-level cell) devices. Additionally or alternatively, the techniques can be applied to various types of devices and systems, such as secure digital (SD) cards, embedded multimedia cards (eMMC), or solid-state drives (SSDs), embedded systems, among others.

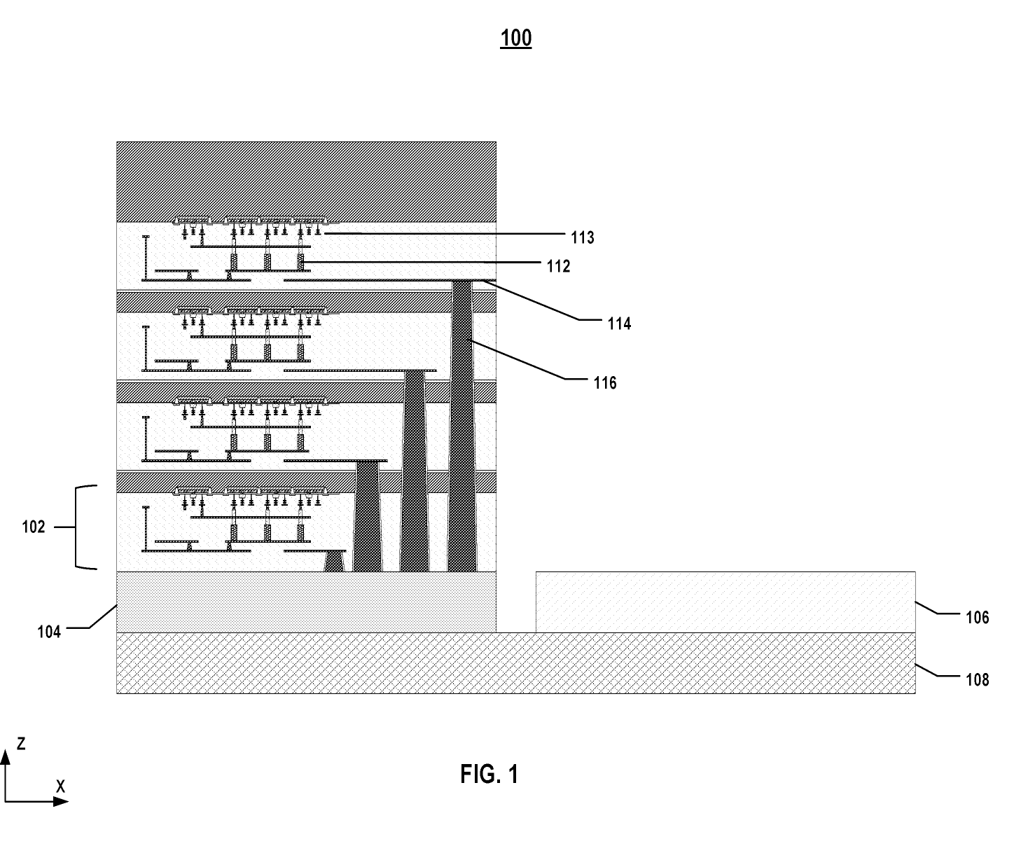

FIG. 1 illustrates a schematic view of a cross-section of a semiconductor structure 100, according to some implementations of the present disclosure. The semiconductor structure 100 includes multiple stacked semiconductor chips 102, and the semiconductor chips 102 are bonded to a base die 104. The base die 104 and a computing die 106 are bonded to an interposer 108, as shown in FIG. 1. In some implementations, the base die 104 is configured to control the semiconductor chips 102, e.g., memory devices, and the base die 104 and the computing die 106 are integrated on the interposer 108 along the X-direction.

In some implementations, the semiconductor chips 102 are bonded through a chip-to-chip bonding layer. In some implementations, the semiconductor chips 102 are bonded to a base die 104 through a direct bonding layer including at least one dielectric material and exclude a conductive bonding contact. In some implementations, the semiconductor chips 102 are bonded to a base die 104 through a hybrid bonding layer including bonding contacts and at least one dielectric material isolating the bonding contacts. In some implementations, the bonding contacts may further connect the interconnect layers or redistribution layers of the semiconductor chips 102. In some implementations, the semiconductor chips 102 are bonded to a base die 104 through a microbump structure. In some implementations, tiny copper bumps are formed on dies and then connected and assembled into a package, providing small, fast electrical connections between the semiconductor chips 102 or between the semiconductor chips 102 and the base die 104.

In some implementations, the semiconductor chips 102 may include the memory device 112, the periphery structure 113, the interconnect layer 114, and the contact structure 116, e.g., TSV. As shown in FIG. 1, signals in each memory device 112 and periphery structure 113 may be coupled to the base die 104 through the interconnect layer 114 extending in the X-direction and the contact structure 116 extending in the Z-direction.

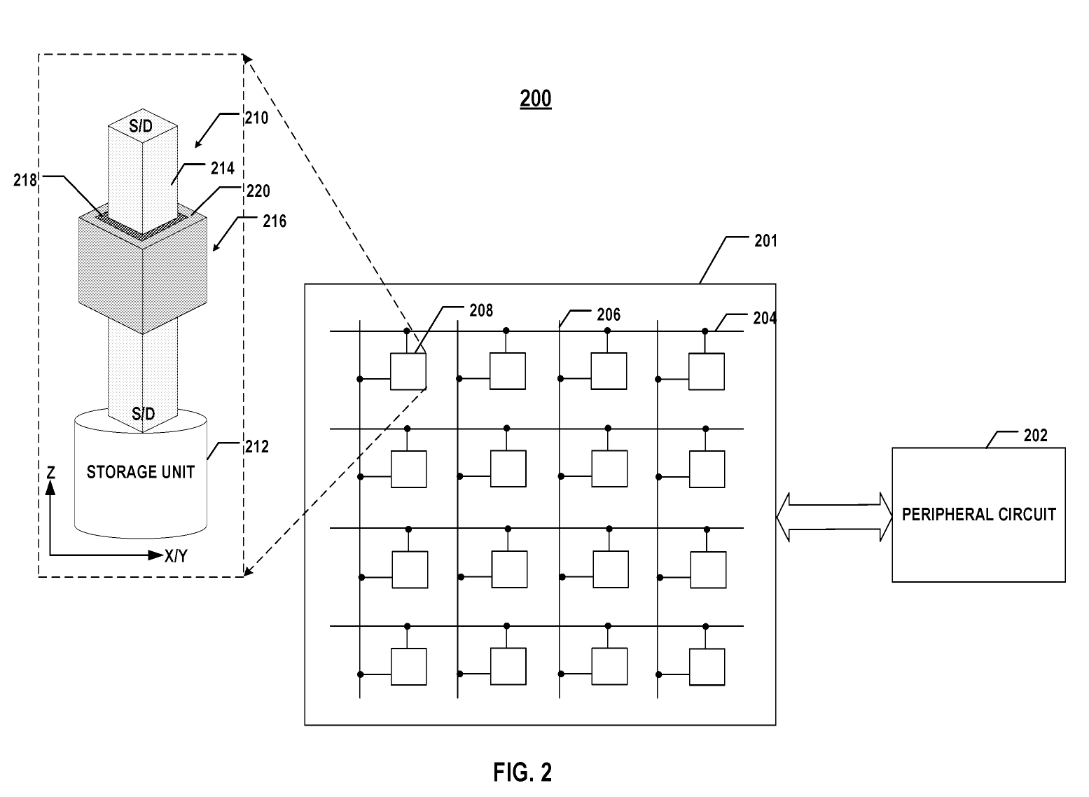

FIG. 2 illustrates a schematic diagram of a memory device 200 including peripheral circuits and an array of memory cells each having a vertical transistor, according to some aspects of the present disclosure. Memory device 200 can include a memory cell array 201 and peripheral circuits 202 coupled to memory cell array 201. The semiconductor chips 102 may be examples of memory device 200 in which the memory device 112 may be the memory cell array 201, and the periphery structure 113 may be the peripheral circuits 202.

The memory cell array 201 can be any suitable memory cell array in which each memory cell 208 includes a vertical transistor 210, and a storage unit 212 coupled to vertical transistor 210. In some implementations, memory cell array 201 is a DRAM cell array, and storage unit 212 is a capacitor for storing charge as the binary information stored by the respective DRAM cell. In some implementations, memory cell array 201 is a PCM cell array, and storage unit 212 is a PCM element (e.g., including chalcogenide alloys) for storing binary information of the respective PCM cell based on the different resistivities of the PCM element in the amorphous phase and the crystalline phase. In some implementations, memory cell array 201 is a FRAM cell array, and storage unit 212 is a ferroelectric capacitor for storing binary information of the respective FRAM cell based on the switch between two polarization states of ferroelectric materials under an external electric field.

As shown in FIG. 2, memory cells 208 can be arranged in a two-dimensional (2D) array having rows and columns. Memory device 200 can include word lines 204 coupling peripheral circuits 202 and memory cell array 201 for controlling the switch of vertical transistors 210 in memory cells 208 located in a row, as well as bit lines 206 coupling peripheral circuits 202 and memory cell array 201 for sending data to and/or receiving data from memory cells 208 located in a column. That is, each word line 204 is coupled to a respective row of memory cells 208, and each bit line is coupled to a respective column of memory cells 208.

Consistent with the scope of the present disclosure, vertical transistors 210, such as vertical metal-oxide-semiconductor field-effect transistors (MOSFETs), can replace the planar transistors as the pass transistors of memory cells 208 to reduce the area occupied by the pass transistors, the coupling capacitance, as well as the interconnect routing complexity, as described below in detail. As shown in FIG. 2, in some implementations, different from planar transistors in which the active regions are formed in the substrates, vertical transistor 210 includes a semiconductor body 214 extending vertically (in the Z-direction) above the substrate (not shown). That is, semiconductor body 214 can extend above the top surface of the substrate to allow channels to be formed not only at the top surface of semiconductor body 214, but also at one or more side surfaces thereof. As shown in FIG. 2, for example, semiconductor body 214 can have a cuboid shape to expose four sides thereof. It is understood that semiconductor body 214 may have any suitable 3D shape, such as a polyhedron shape or a cylinder shape. That is, the cross-section of semiconductor body 214 in the plan view (e.g., in the X-Y plane) can have a square shape, a rectangular shape (or a trapezoidal shape), a circular (or an oval shape), or any other suitable shapes. It is understood that consistent with the scope of the present disclosure, for semiconductor bodies that have a circular or oval shape of their cross-sections in the plan view, the semiconductor bodies may still be considered as having multiple sides, such that the gate structures are in contact with more than one side of the semiconductor bodies. As described below with respect to the fabrication process, semiconductor body 214 can be formed from the substrate (e.g., by etching or epitaxy) and thus, has the same semiconductor material (e.g., silicon crystalline silicon) as the substrate (e.g., a silicon substrate).

As shown in FIG. 2, vertical transistor 210 can also include a gate structure 216 in contact with one or more sides of semiconductor body 214, e.g., in one or more planes of the side surface(s) of the active region. In other words, the active region of vertical transistor 210, e.g., semiconductor body 214, can be at least partially surrounded by gate structure 216. Gate structure 216 can include a gate dielectric 218 over one or more sides of semiconductor body 214, e.g., in contact with four side surfaces of semiconductor body 214, as shown in FIG. 2. Gate structure 216 can also include a gate electrode 220 over and in contact with gate dielectric 218. Gate dielectric 218 can include any suitable dielectric materials, such as silicon oxide, silicon nitride, silicon oxynitride, or high-k dielectrics. For example, gate dielectric 218 may include silicon oxide, which is a form of gate oxide. Gate electrode 220 can include any suitable conductive materials, such as polysilicon, metals (e.g., tungsten (W), copper (Cu), aluminum (Al), etc.), metal compounds (e.g., titanium nitride (TiN), tantalum nitride (TaN), etc.), or silicides. For example, gate electrode 220 may include doped polysilicon, which is a form of a gate poly. In some implementations, gate electrode 220 includes multiple conductive layers, such as a W layer over a TiN layer. It is understood that gate electrode 220 and word line 204 may be a continuous conductive structure in some examples. In other words, gate electrode 220 may be viewed as part of word line 204 that forms gate structure 216, or word line 204 may be viewed as the extension of gate electrode 220 to be coupled to peripheral circuits 202.

As shown in FIG. 2, vertical transistor 210 can further include a pair of a source and a drain (S/D, dope regions, a.k.a., source electrode and drain electrode) formed at the two ends of semiconductor body 214 in the vertical direction (the z-direction), respectively. The source and drain can be doped with any suitable P-type dopants, such as boron (B) or Gallium (Ga), or any suitable N-type dopants, such as phosphorus (P) or arsenic (As). The source and drain can be separated by gate structure 216 in the vertical direction (the z-direction). In other words, gate structure 216 is formed vertically between the source and drain. As a result, one or more channels (not shown) of vertical transistor 210 can be formed in semiconductor body 214 vertically between the source and drain when a gate voltage applied to gate electrode 220 of gate structure 216 is above the threshold voltage of vertical transistor 210. That is, each channel of vertical transistors 210 is also formed in the vertical direction along which semiconductor body 214 extends, according to some implementations.

In some implementations, as shown in FIG. 2, vertical transistor 210 is a multi-gate transistor. That is, gate structure 216 can be in contact with more than one side of semiconductor body 214 (e.g., four sides in FIG. 2) to form more than one gate, such that more than one channel can be formed between the source and drain in operation. That is, different from the planar transistor that includes only a single planar gate (and resulting in a single planar channel), vertical transistor 210 shown in FIG. 2 can include multiple vertical gates on multiple sides of semiconductor body 214 due to the 3D structure of semiconductor body 214 and gate structure 216 that surrounds the multiple sides of semiconductor body 214. As a result, compared with planar transistors, vertical transistor 210 shown in FIG. 2 can have a larger gate control area to achieve better channel control with a smaller subthreshold swing. Since the channel is fully depleted, the leakage current (_{Ioff}) of vertical transistor 210 can be significantly reduced as well. As described below in detail, the multi-gate vertical transistors can include double-gate vertical transistors (e.g., dual-side gate vertical transistors), tri-gate vertical transistors (e.g., tri-side gate vertical transistors), and GAA vertical transistors.

It is understood that although vertical transistor 210 is shown as a multi-gate transistor in FIG. 2, the vertical transistors disclosed herein may also include single-gate transistors as described below in detail. That is, gate structure 216 may be in contact with a single side of semiconductor body 214, for example, for the purpose of increasing the transistor and memory cell density. It is also understood that although gate dielectric 218 is shown as being separate (a separate structure) from other gate dielectrics of adjacent vertical transistors (not shown), gate dielectric 218 may be part of a continuous dielectric layer having multiple gate dielectrics of vertical transistors.

In planar transistors and some lateral multiple-gate transistors (e.g., FinFET), the active regions, such as semiconductor bodies (e.g., Fins), extend laterally (in the X-Y plane), and the source and the drain are disposed at different locations in the same lateral plane (the X-Y plane). In contrast, in vertical transistor 210, semiconductor body 214 extends vertically (in the Z-direction), and the source and the drain are disposed in the different lateral planes, according to some implementations. In some implementations, the source and the drain are formed at two ends of semiconductor body 214 in the vertical direction (the Z-direction), respectively, thereby being overlapped in the plan view. As a result, the area (in the X-Y plane) occupied by vertical transistor 210 can be reduced compared with planar transistors and lateral multiple-gate transistors. Also, the metal wiring coupled to vertical transistors 210 can be simplified as well since the interconnects can be routed in different planes. For example, bit lines 206 and storage units 212 may be formed on opposite sides of vertical transistor 210. In one example, bit line 206 may be coupled to the source or the drain at the upper end of semiconductor body 214, while storage unit 212 may be coupled to the other source or the drain at the lower end of semiconductor body 214.

As shown in FIG. 2, storage unit 212 can be coupled to the source or the drain of vertical transistor 210. Storage unit 212 can include any devices that are capable of storing binary data (e.g., 0 and 1), including but not limited to, capacitors for DRAM cells and FRAM cells, and PCM elements for PCM cells. In some implementations, vertical transistor 210 controls the selection and/or the state switch of the respective storage unit 212 coupled to vertical transistor 210.

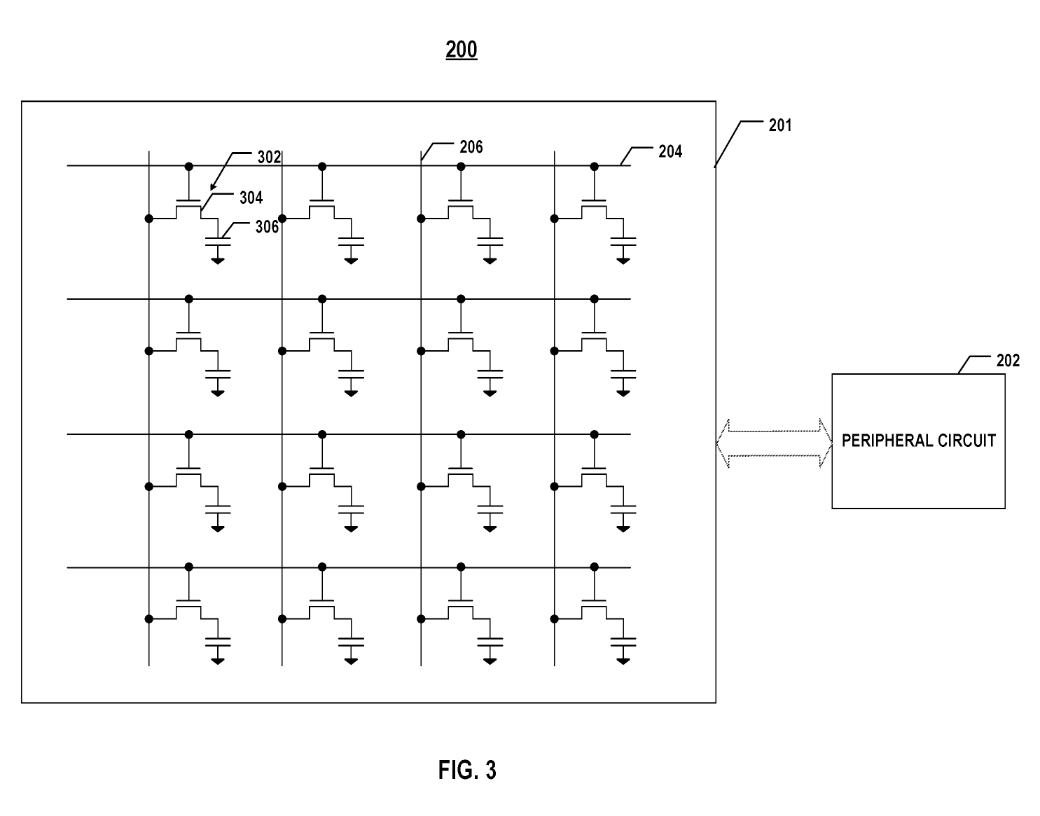

FIG. 3 illustrates a schematic diagram of memory device 200 including peripheral circuits and an array of memory cells each having a vertical transistor, according to some aspects of the present disclosure. In some implementations as shown in FIG. 3, each memory cell 208 is a DRAM cell 302 including a transistor 304 (e.g., implementing using vertical transistors 210 in FIG. 2) and a capacitor 306 (e.g., an example of storage unit 212 in FIG. 2). The gate of transistor 304 (e.g., corresponding to gate electrode 220) may be coupled to word line 204, one of the source and the drain of transistor 304 may be coupled to bit line 206, the other one of the source and the drain of transistor 304 may be coupled to one electrode of capacitor 306, and the other electrode of capacitor 306 may be coupled to the ground.

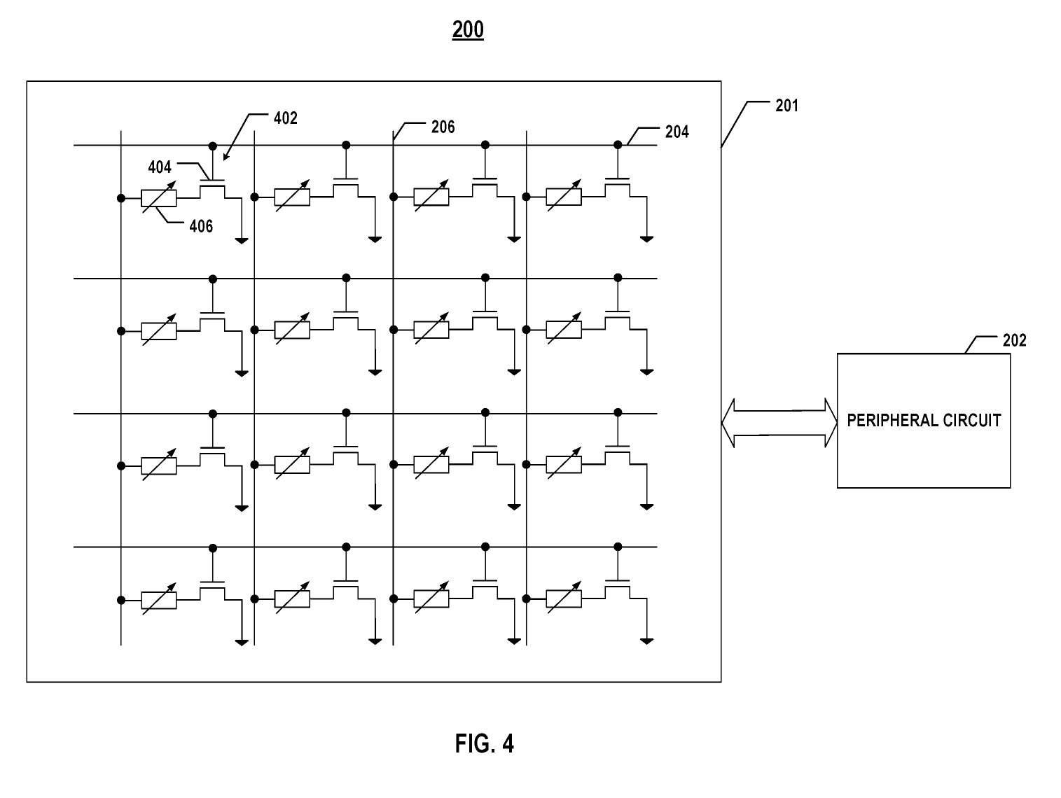

FIG. 4 illustrates a schematic diagram of memory device 200 including peripheral circuits and an array of memory cells each having a vertical transistor, according to some aspects of the present disclosure. In some implementations as shown in FIG. 4, each memory cell 208 is a PCM cell 402 including a transistor 404 (e.g., implementing using vertical transistors 210 in FIG. 2) and a PCM element 406 (e.g., an example of storage unit 212 in FIG. 2). The gate of transistor 404 (e.g., corresponding to gate electrode 220) may be coupled to word line 204, one of the source and the drain of transistor 404 may be coupled to the ground, the other one of the source and the drain of transistor 404 may be coupled to one electrode of PCM element 406, and the other electrode of PCM element 406 may be coupled to bit line 206.

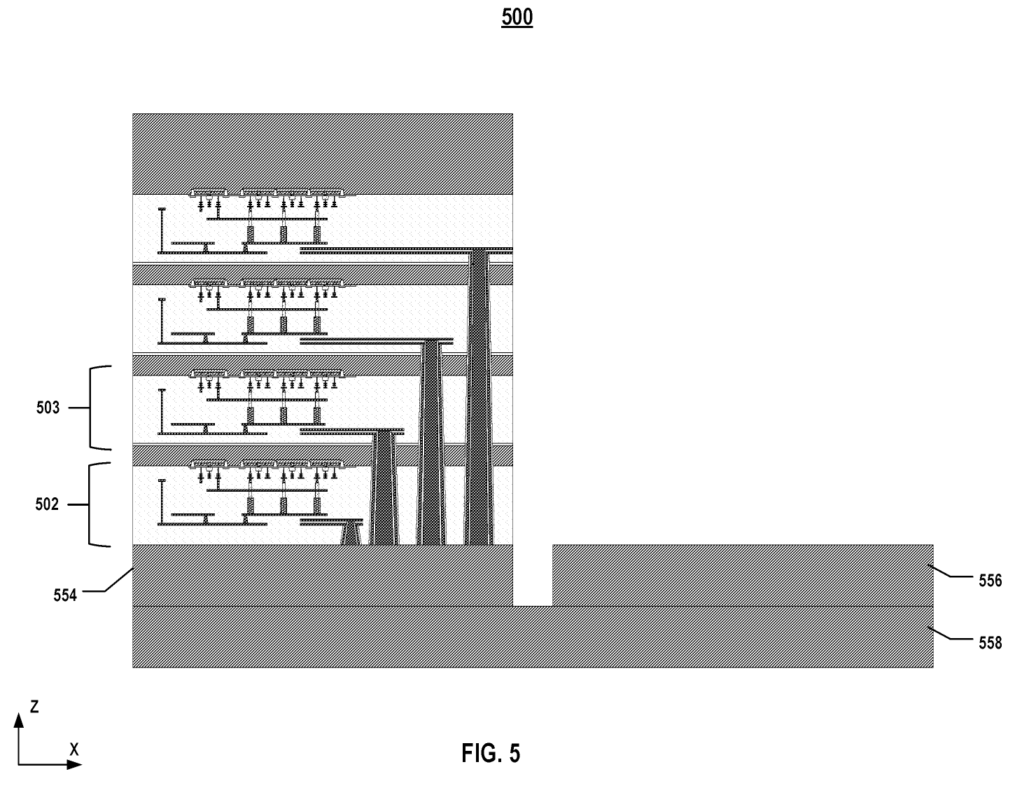

FIG. 5 illustrates a schematic view of a cross-section of a semiconductor structure, e.g., memory device 500, according to some implementations of the present disclosure. The memory device 500 may include a first semiconductor chip 502 and a second semiconductor chip 503 stacking with the first semiconductor chip 502 along the Z-direction. The memory device 500 further includes a base die 554 stacking with the first semiconductor chip 502 and the second semiconductor chip 503 along the Z-direction. The base die 554 and a computing die 556 are bonded to an interposer 558, as shown in FIG. 5. In some implementations, the base die 554 is configured to control the memory device, and the base die 554 and the computing die 556 are integrated on the interposer 558 along the X-direction.

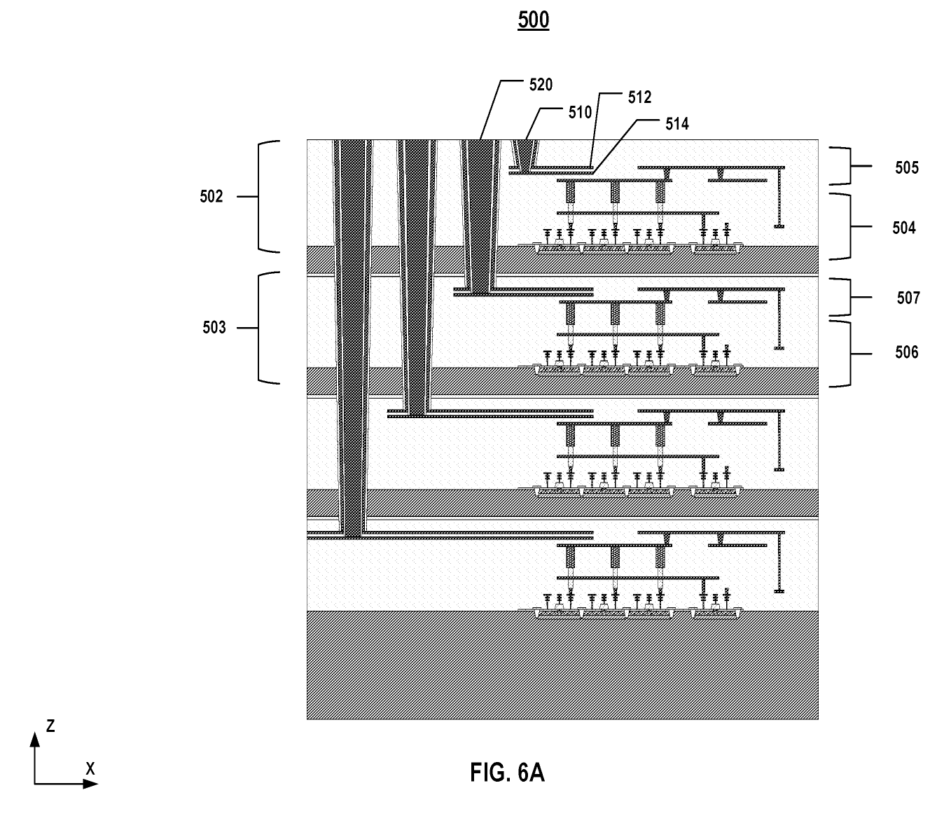

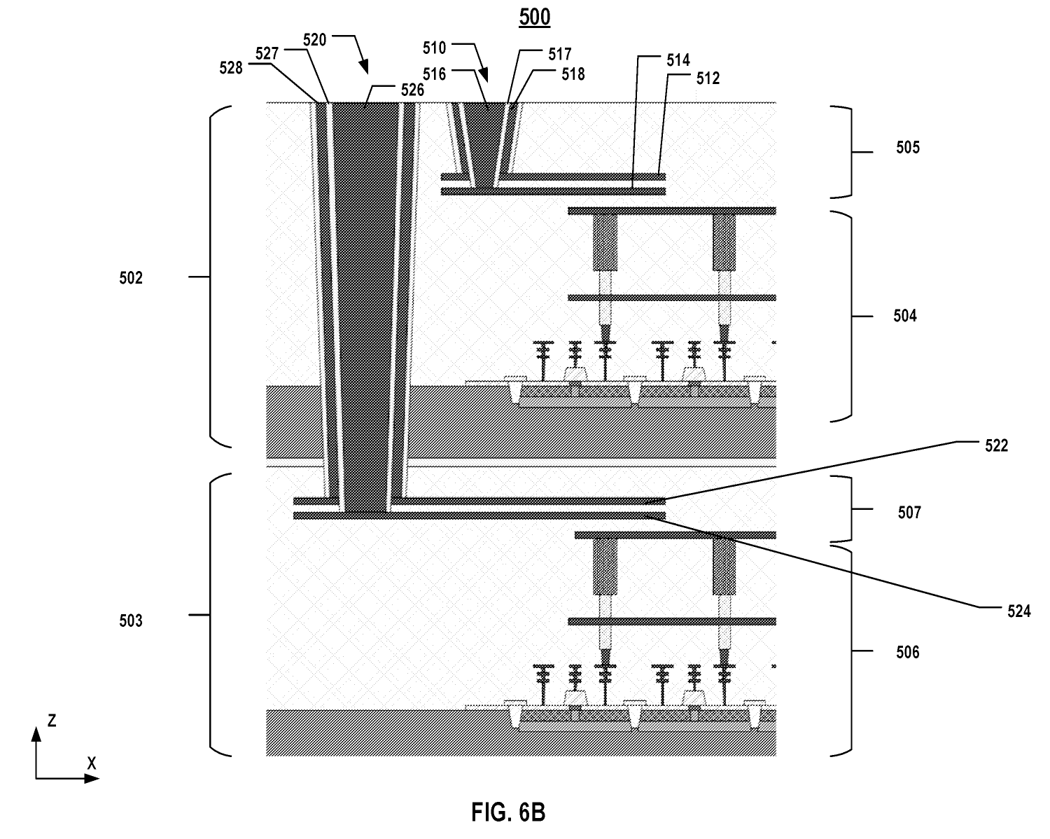

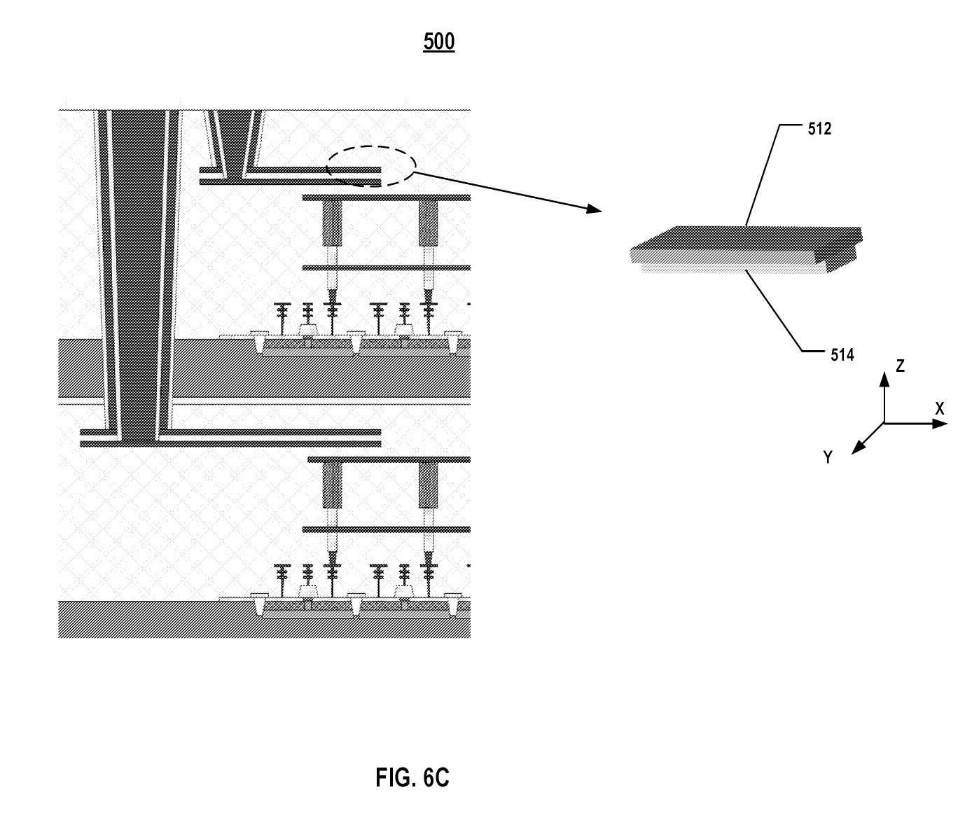

FIG. 6A illustrates a schematic view of a cross-section of partial of the memory device 500, according to some implementations of the present disclosure. The memory device 500 includes the first semiconductor chip 502 and the second semiconductor chip 503 along the Z-direction. The first semiconductor chip 502 includes a first semiconductor structure 504 and a first interconnection structure 505, and the second semiconductor chip 503 includes a second semiconductor structure 506 and a second interconnection structure 507. The memory device 500 further includes a first contact structure 510 extending along the Z-direction in the first semiconductor chip 502 in contact with the first interconnection structure 505. The memory device 500 also includes a second contact structure 520 extending along the Z-direction in both the first semiconductor chip 502 and the second semiconductor chip 503, and the second contact structure 520 is in contact with the second interconnection structure 507. In some implementations, the second contact structure 520 penetrates the first semiconductor chip 502 and extends into the second semiconductor chip 503 to contact the second interconnection structure 507. In some implementations, the second contact structure 520 penetrates the substrate of the first semiconductor chip 502.

As shown in FIG. 6B, the first contact structure 510 includes a first inner conductive layer 516 and a first outer conductive layer 518 surrounding the first inner conductive layer 516, and the first interconnection structure 505 extends along the X-direction perpendicular to the Z-direction in contact with the first contact structure 510. The second contact structure 520 includes a second inner conductive layer 526 and a second outer conductive layer 528 surrounding the second inner conductive layer 526. The second interconnection structure 5507 extends along the X-direction perpendicular to the Z-direction in contact with the second contact structure 520.

The first inner conductive layer 516 and the first outer conductive layer 518 are arranged along the X-direction, and the second inner conductive layer 526 and the second outer conductive layer 528 are also arranged along the X-direction. In some implementations, the second contact structure 520 extends along the Z-direction in contact with the second interconnection structure 507 without contacting the first interconnection structure 505. In other words, the first contact structure 510 only contacts the first interconnection structure 505, and the second contact structure 520 only contacts the second interconnection structure 507 without contacting the first interconnection structure 505.

In some implementations, the first contact structure 510 further includes a first dielectric layer 517 disposed between the first inner conductive layer 516 and the first outer conductive layer 518, and the second contact structure 520 further includes a second dielectric layer 527 disposed between the second inner conductive layer 526 and the second outer conductive layer 528. In some implementations, the length of the first inner conductive layer 516 along the Z-direction is greater than the length of the first outer conductive layer 518 along the Z-direction. In some implementations, the length of the second inner conductive layer 526 along the Z-direction is greater than the length of the second outer conductive layer 528 along the Z-direction.

As shown in FIGS. 6A and 6B, the first interconnection structure 505 includes a first conductive line 512 extending along the X-direction and a second conductive line 514 extending along the X-direction. In some implementations, the first conductive line 512 is parallel to the second conductive line 514. The second interconnection structure 507 includes a third conductive line 522 extending along the X-direction and a fourth conductive line 524 extending along the X-direction. In some implementations, the third conductive line 522 is parallel to the fourth conductive line 524.

In some implementations, the first outer conductive layer 518 is in contact with the first conductive line 512, and the first inner conductive layer 516 is in contact with the second conductive line 514. In some implementations, the second outer conductive layer 528 is in contact with the third conductive line 522, and the second inner conductive layer 526 is in contact with the fourth conductive line 524. As shown in FIG. 6B, in some implementations, a length of the second contact structure 520 along the Z-direction is greater than a length of the first contact structure 510 along the Z-direction. In some implementations, a length of the second interconnection structure 507 along the X-direction is greater than a length of the first interconnection structure 505 along the X-direction.

FIG. 6C illustrates a schematic view of a cross-section of partial of the memory device 500, according to some implementations of the present disclosure. As shown in FIG. 6C, the dimensions of the first conductive line 512 and the second conductive line 514 may be different. In some implementations, a width of the first conductive line 512 along the Y-direction perpendicular to the X-direction and the Z-direction is greater than a width of the second conductive line 514 along the Y-direction. In some implementations, a width of the third conductive line 522 along the Y-direction is greater than a width of the fourth conductive line 524 along the Y-direction.

Since the second conductive line 514 is in contact with the first inner conductive layer 516 and the first conductive line 512 is in contact with the first outer conductive layer 518, when the area of the first outer conductive layer 518 is greater than the area of the first inner conductive layer 516, the width of the first conductive line 512 may be greater than the width of the second conductive line 514 for the TSV landing. However, in other implementations, the width of the first conductive line 512 and the width of the second conductive line 514 may be designed the same.

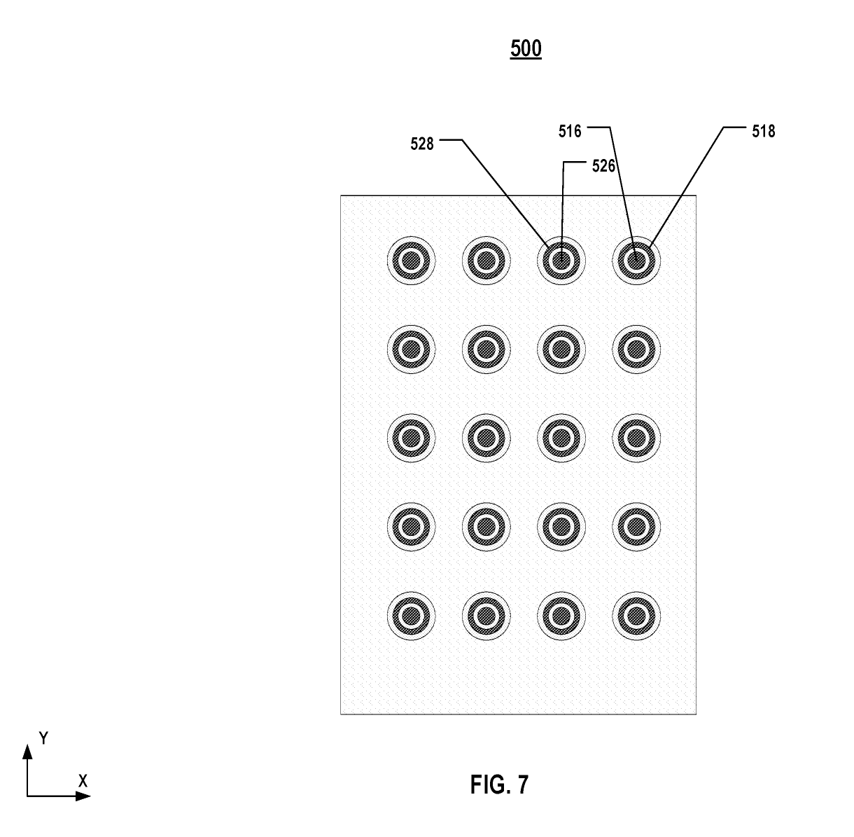

FIG. 7 illustrates a schematic view of a plan view of a semiconductor structure, according to some implementations of the present disclosure. As shown in FIG. 7, the first inner conductive layer 516 and the first outer conductive layer 518 form a pattern of concentric circles in the plan view of the memory device 500. In addition, as shown in FIGS. 6A-6C, the first inner conductive layer 516 and the first outer conductive layer 518 form a concentric column extending along the Z-direction. In some implementations, the diameter of the first inner conductive layer 516 is between 1 micrometer and 10 micrometers. In some implementations, the diameter of the first inner conductive layer 516 is between 1 micrometer and 5 micrometers. In some implementations, the diameter of the first outer conductive layer 518 is between 3 micrometers and 20 micrometers. In some implementations, the diameter of the first outer conductive layer 518 is between 3 micrometers and 10 micrometers.

In some implementations, the first semiconductor structure 504 includes a memory array and a periphery circuit, and the first contact structure is coupled to the periphery circuit through the first interconnection structure 505. In some implementations, the memory array includes a memory element and a capacitor, and the memory element and the capacitor are arranged along the Z-direction. In some implementations, the memory device 500 may further include a base die 554 stacking with the first semiconductor chip 502 and the second semiconductor chip 503 along the Z-direction. In some implementations, the first contact structure 510 and the second contact structure 520 are in contact with the base die 554, as shown in FIG. 5. In some implementations, the second semiconductor chip 503 is stacked with the first semiconductor chip 502 through a dielectric layer.

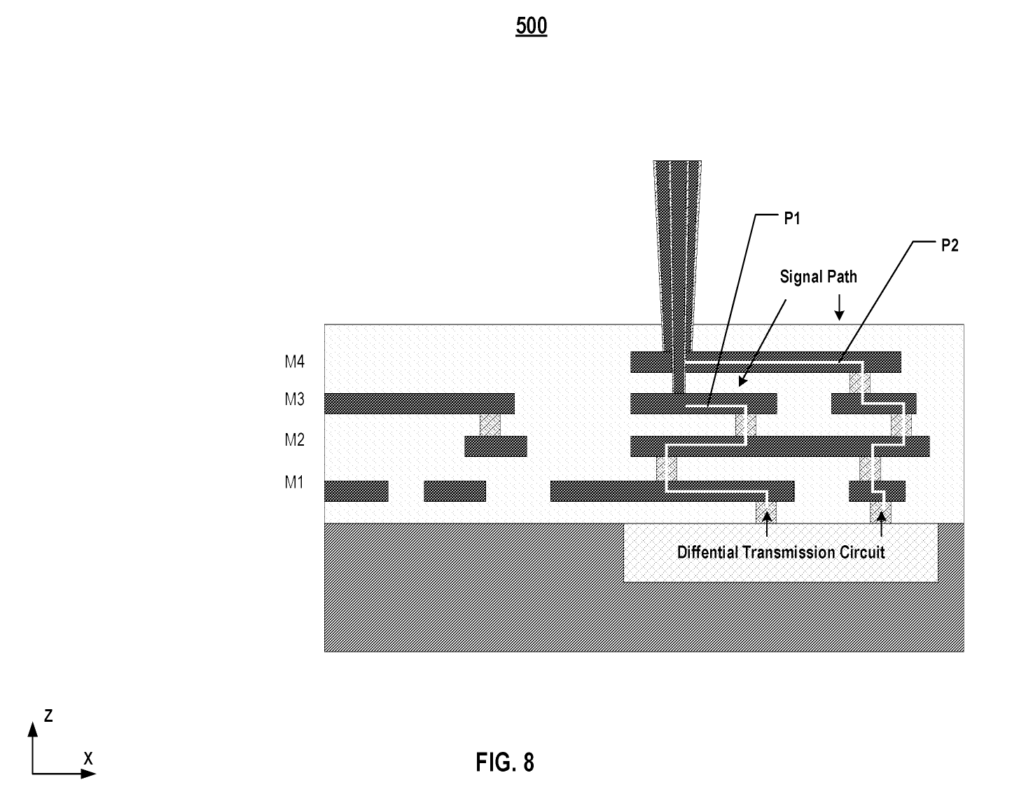

FIG. 8 illustrates a schematic view of a cross-section of the memory device 500 showing the differential transmission path, according to some implementations of the present disclosure. As sown in FIG. 8, the differential transmission path includes a path P1 and a path P2. In some implementations, the path P1 is the path from the differential transmission circuit to the first inner conductive layer 516, and the path P2 is the path from the differential transmission circuit to the first outer conductive layer 518. In some implementations, the first inner conductive layer 516 is connected to the metal 3 layer (M3), and the first outer conductive layer 518 is connected to the metal 4 layer (M4). In other words, the first inner conductive layer 516 and the first outer conductive layer 518 are landed on different metal layers. In some implementations, the length of the path P1 and the path P2 may be substantially the same by adaptively design the routing or wiring of the path through multiple metal layers.

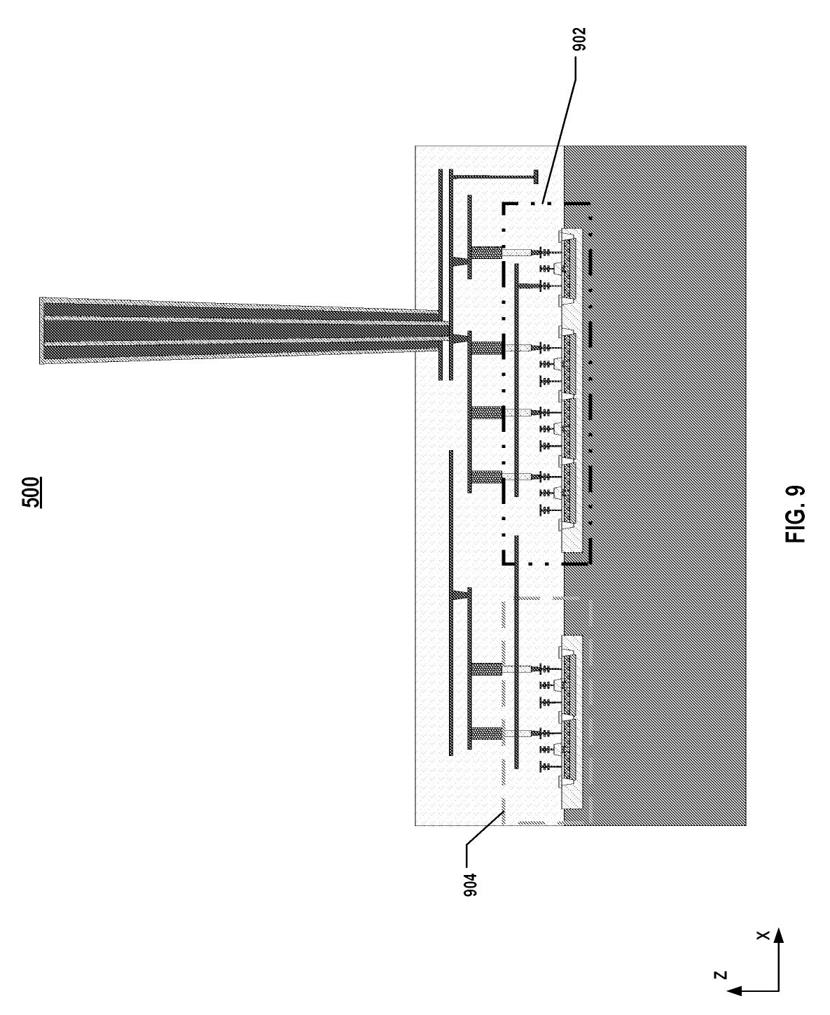

FIG. 9 illustrates a schematic view of a cross-section of the memory device 500 showing the differential operation circuit, according to some implementations of the present disclosure. As shown in FIG. 9, the first semiconductor structure 504 may include a differential transmission circuit 902, e.g., a low-voltage differential signal transmission circuit, and a data buffer circuit 904. In some implementations, the data buffer circuit 904 transmits the control signals to the differential transmission circuit 902 to control the driving of the differential signals.

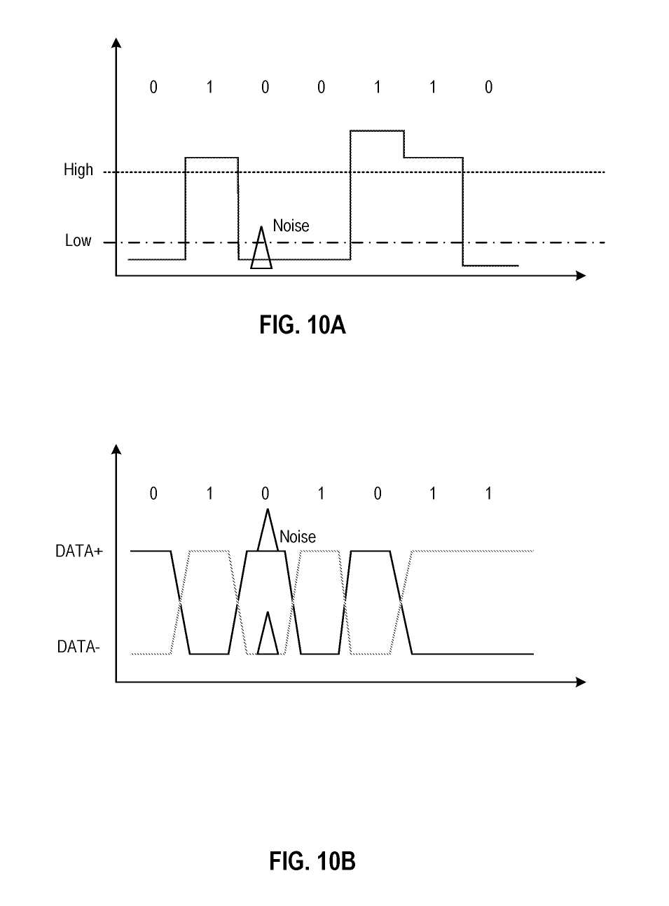

FIGS. 10A-10B illustrate schematic views of a single-end transmission operation and a differential transmission operation, according to some implementations of the present disclosure. As shown in FIG. 10A, the single-end transmission operation receives one signal and compares the signal with two reference voltage levels, High and Low, to determine the value of the signal. When a noise appears on the path of transmission, the result of determination would be seriously affected. Hence, there is severe crosstalk between signals and the transmission is very susceptible to interference. As shown in FIG. 10 B, the signal value in the differential transmission operation is determined by the phase difference between two signals and the phase difference is a relative value. When a noise appears on the transmission path, both signals would be changed accordingly and the related value would remain substantially the same. Hence, the differential transmission operation has a strong anti-interference ability.

By using the first contact structure 510 and the second contact structure 520 having the inner conductive layers and the outer conductive layers connected to different metal layers, e.g., the conductive lines 512, 514, 522, and 514, the differential transmission of the signals can be achieved to resist external interference to the signals. In addition, by using the first contact structure 510 and the second contact structure 520 having the inner conductive layers and the outer conductive layers, a higher signal transmission frequency can be achieved without increasing the number of TSVs.

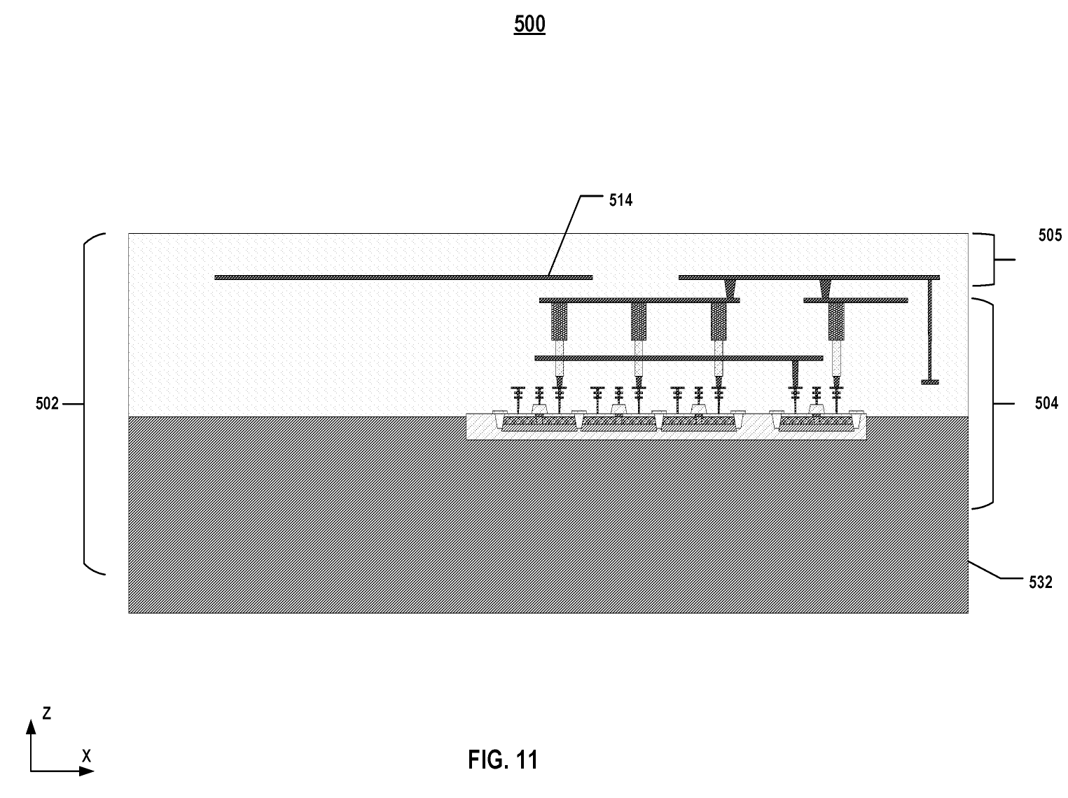

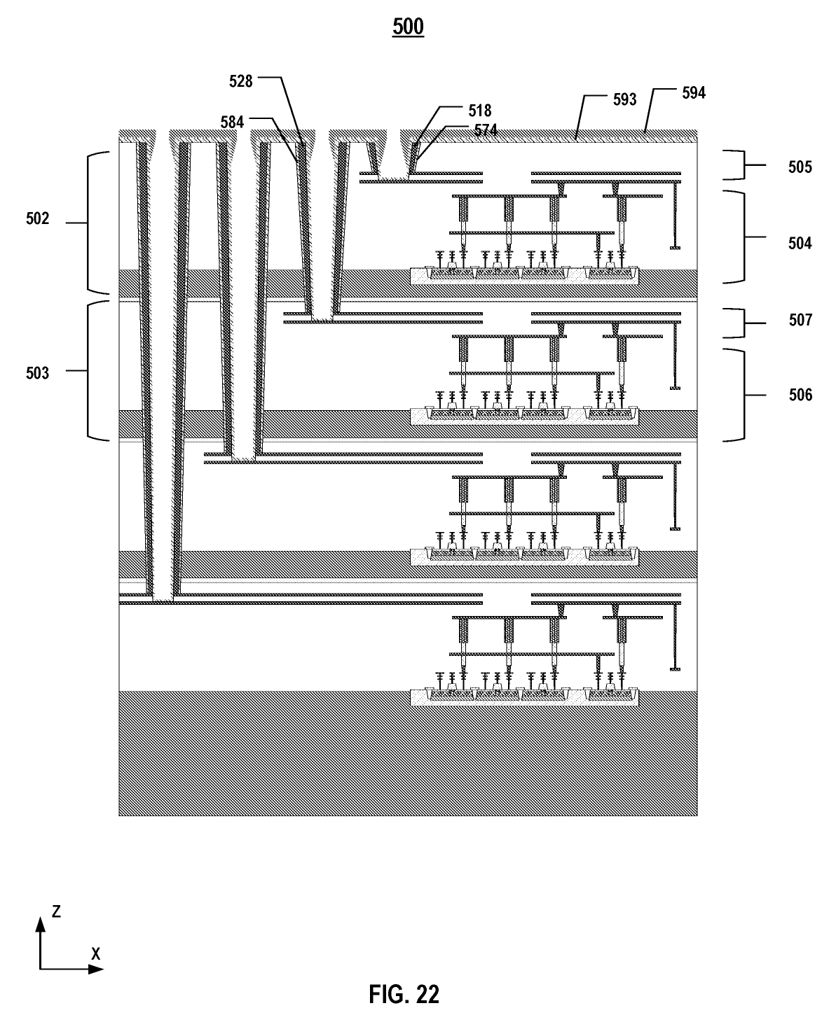

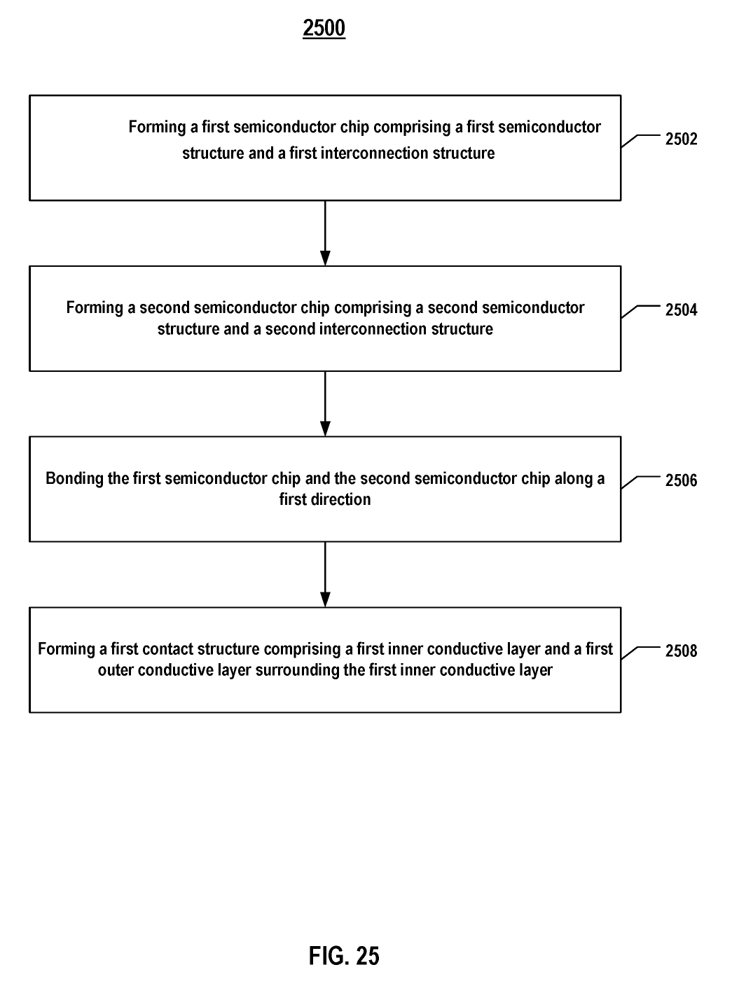

FIGS. 11-24 illustrate cross-sectional views of the memory device 500 at various stages of a fabrication process, according to some implementations of the present disclosure. FIG. 25 illustrates a flowchart of a method for forming the memory device 500, according to some implementations of the present disclosure. For the purpose of better describing the present disclosure, the memory device 500 in FIGS. 11-24 and method 2500 in FIG. 25 will be discussed together. It is understood that the operations shown in method 2500 are not exhaustive and that other operations may be performed as well before, after, or between any of the illustrated operations. Further, some of the operations may be performed simultaneously, or in a different order than shown in FIGS. 11-24 and 25.

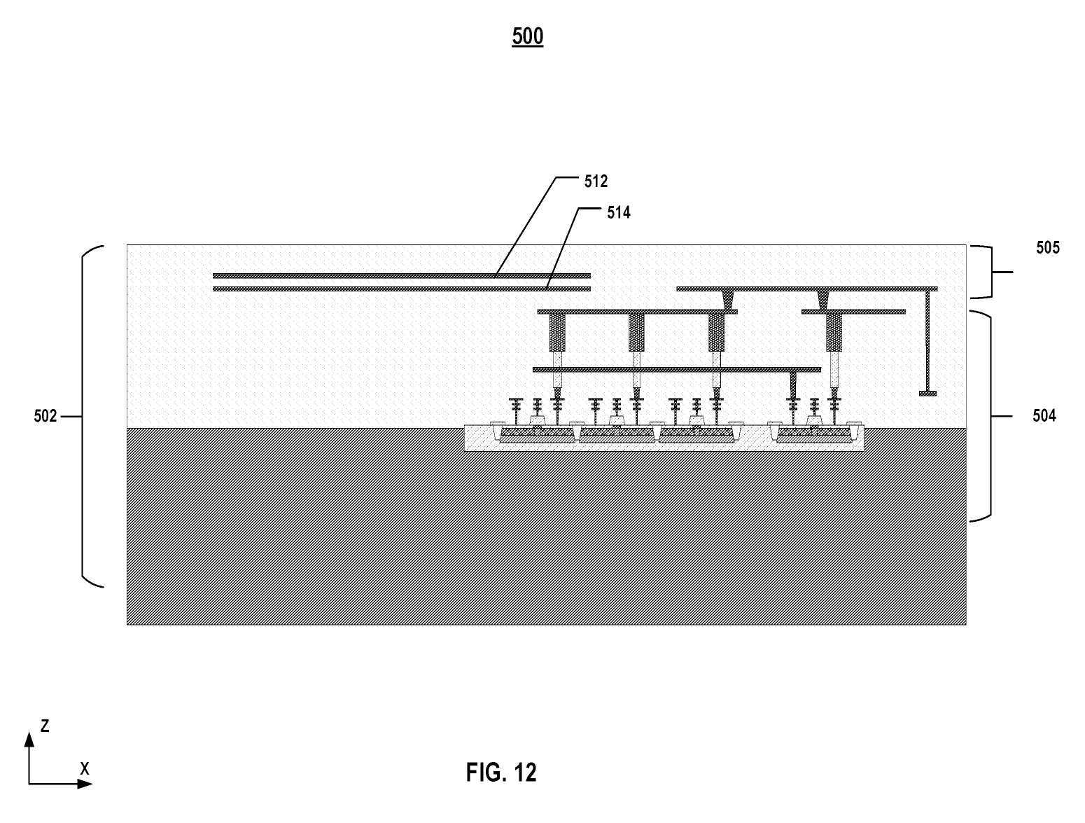

As shown in FIG. 11 and operation 2502 of FIG. 25, a first semiconductor chip 502 is formed. The first semiconductor chip 502 includes a first semiconductor structure 504 and a first interconnection structure 505. In some implementations, the first semiconductor structure 504 is formed on a substrate 532, and a first conductive line 512 and a second conductive line 514 are formed on the first semiconductor structure 504, as shown in FIGS. 11 and 12. In some implementations, the first conductive line 512 and the second conductive line 514 extend along the X-direction. The second conductive line 514 is located between the first conductive line 512 and the first semiconductor structure 504 along the Z-direction, and the first conductive line 512 is parallel to the second conductive line 514. In some implementations, the first conductive line 512 and the second conductive line 514 may be formed by metals, e.g., tungsten (W), copper (Cu), aluminum (Al), etc. In some implementations, the first conductive line 512 and the second conductive line 514 are covered by a dielectric layer. In some implementations, the first semiconductor structure 504 includes a memory array and a periphery circuit. In some implementations, the memory array includes a memory element and a capacitor, and the memory element and the capacitor are arranged along the Z-direction.

As shown in operation 2504 of FIG. 25, a second semiconductor chip 503 is formed. The second semiconductor chip 503 includes a second semiconductor structure 506 and a second interconnection structure 507. In some implementations, the process of forming the second semiconductor chip 503 may be similar to the process of forming the first semiconductor chip 502. In some implementations, the first semiconductor chip 502 and the second semiconductor chip 503 may be formed simultaneously on different substrates. In some implementations, the first semiconductor chip 502 and the second semiconductor chip 503 may be formed simultaneously on the same substrates. In some implementations, the first semiconductor chip 502 and the second semiconductor chip 503 may be formed sequentially on different substrates. In some implementations, the first semiconductor chip 502 and the second semiconductor chip 503 may be formed sequentially on the same substrates.

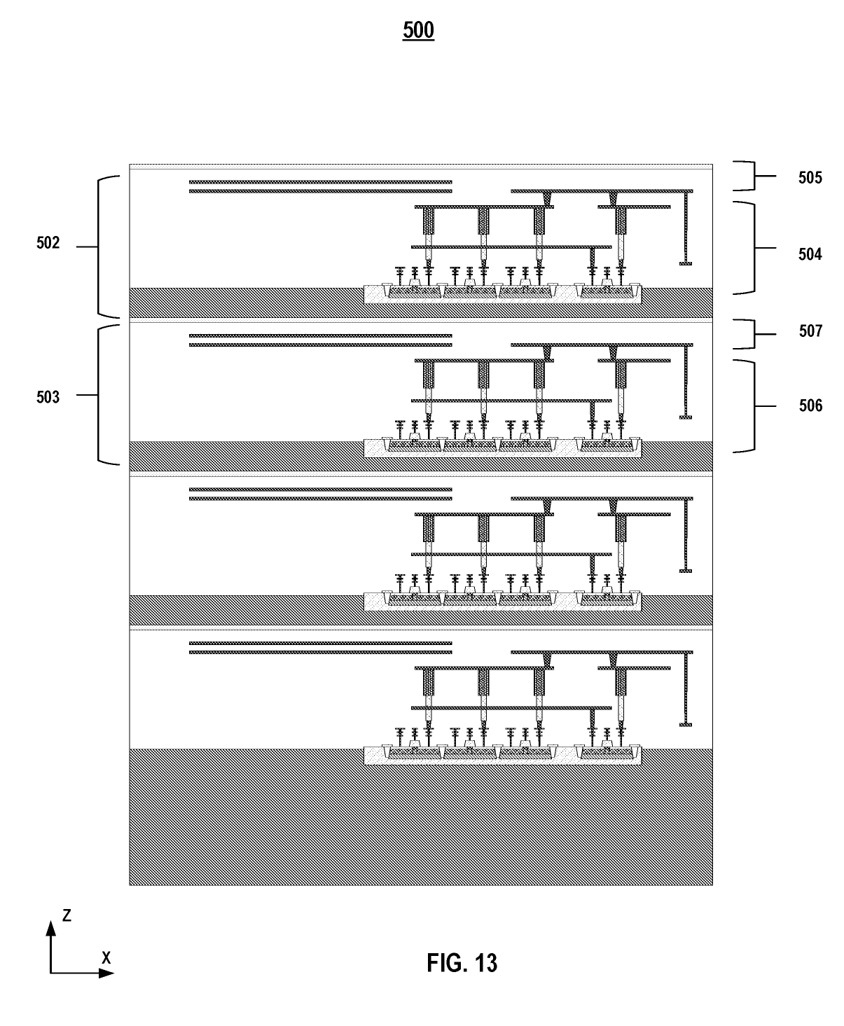

As shown in FIG. 13 and operation 2506 of FIG. 25, the first semiconductor chip 502 and the second semiconductor chip 503 are bonded along the Z-direction. In some implementations, before bonding the first semiconductor chip 502 and the second semiconductor chip 503, a chip-to-chip bonding layer may be formed on the first semiconductor chip 502 and the second semiconductor chip 503. In some implementations, the chip-to-chip bonding layer may include only the dielectric material. In other words, there is no metal contact in the chip-to-chip bonding layer. In some implementations, the chip-to-chip bonding layer may include a hybrid dielectric-to-dielectric and metal-to-metal bonding layer. In some implementations, the chip-to-chip bonding layer includes the metal structure and the dielectric bonding material.

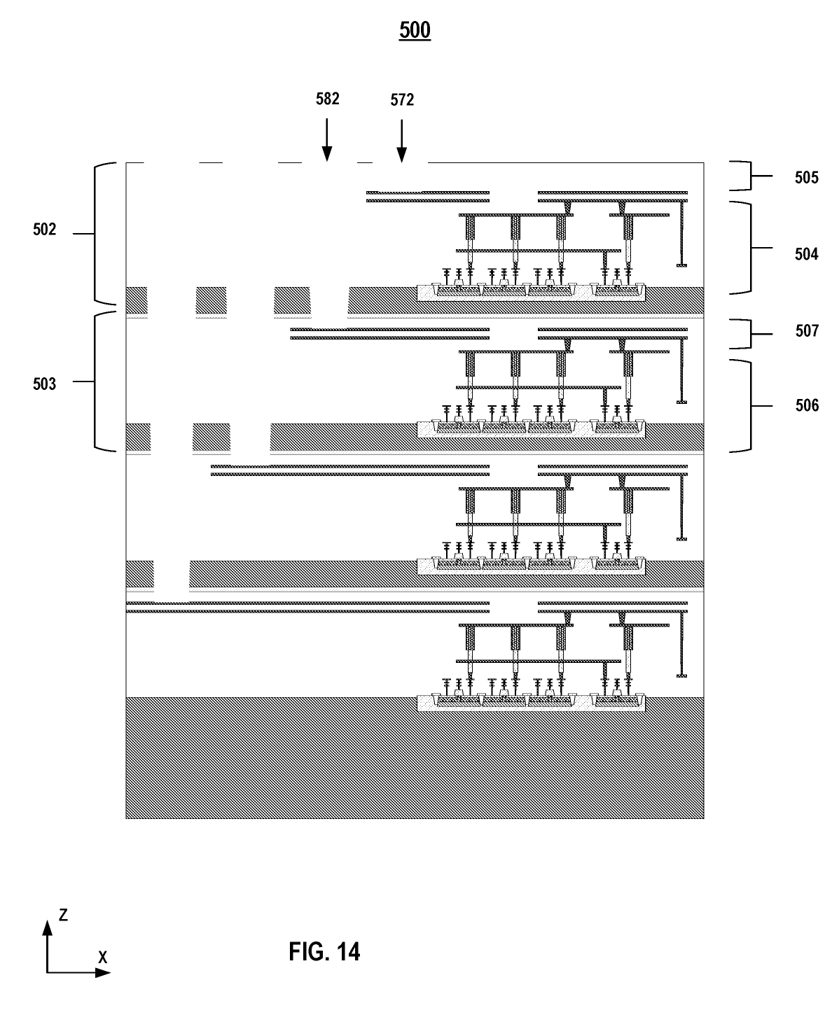

As shown in FIGS. 14-24 and operation 2508 of FIG. 25, a first contact structure 510 is formed. The first contact structure 510 includes a first inner conductive layer 516 and a first outer conductive layer 518 surrounding the first inner conductive layer 516. In some implementations, the first contact structure 510 is a first concentric column composed of the first inner conductive layer 516 and the first outer conductive layer 518 surrounding the first inner conductive layer 516. In some implementations, the first contact structure 510 extends along the Z-direction in the first semiconductor chip 502 in contact with the first interconnection structure 505, and the first interconnection structure 505 extends along the X-direction perpendicular to the Z-direction.

As shown in FIGS. 14-24, a second contact structure 520 is further formed. The second contact structure 520 includes a second inner conductive layer 526 and a second outer conductive layer 528 surrounding the second inner conductive layer 526. In some implementations, the second contact structure 520 is a second concentric column composed of the second inner conductive layer 526 and the second outer conductive layer 528 surrounding the second inner conductive layer 526. The second contact structure 520 extends along the Z-direction in the first semiconductor chip 502 and the second semiconductor chip 503, and the second contact structure 520 is in contact with the second interconnection structure 507.

As shown in FIG. 14, a first opening 572 is formed extending along the Z-direction in the first semiconductor chip 502 exposing the first interconnection structure 505. In some implementations, the first opening 572 extends along the Z-direction in the first semiconductor chip 502 exposing the first conductive line 512. In some implementations, the first opening 572 is formed by etching operation. In some implementations, the first opening 572 extends only to the first semiconductor chip 502.

Further, as shown in FIG. 14, a second opening 582 is formed extending along the Z-direction in the first semiconductor chip 502 and the second semiconductor chip 503 exposing the second interconnection structure 507. In some implementations, the second opening 582 extends along the Z-direction in the first semiconductor chip 502 and the second semiconductor chip 503 exposing the third conductive line 522. In some implementations, the second opening 582 is formed by etching operation. In some implementations, the second opening 582 penetrates the first semiconductor chip 502 and extends into the second semiconductor chip 503.

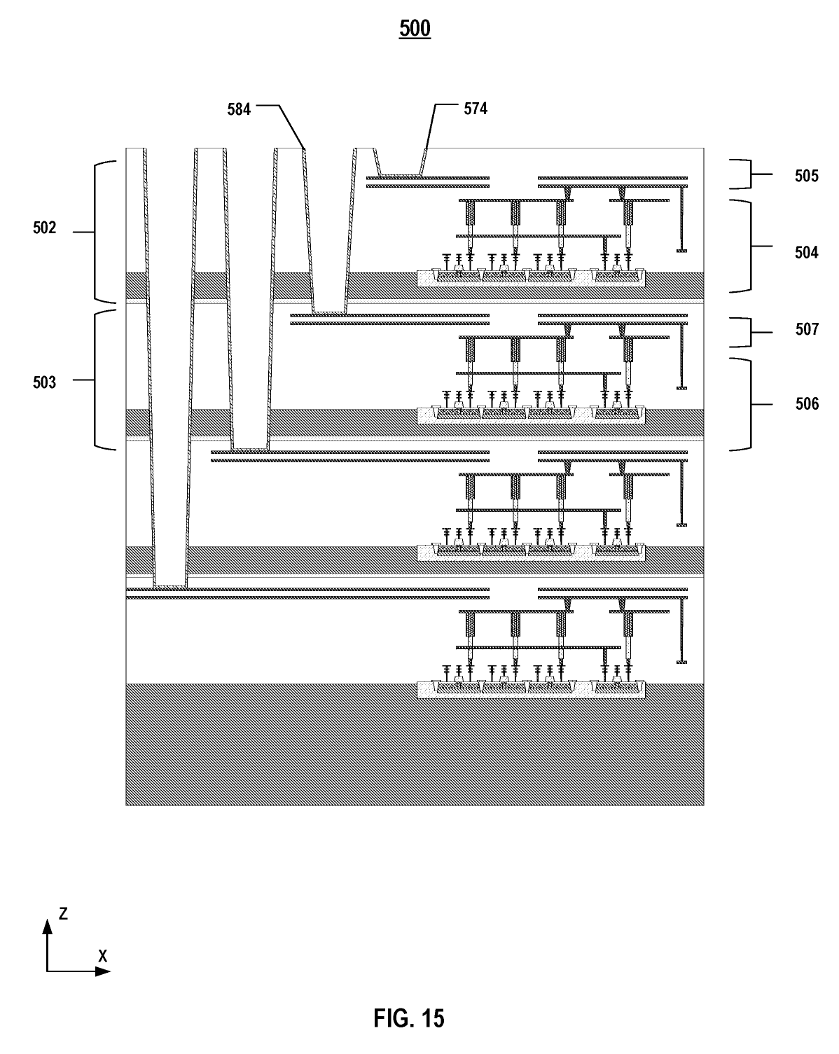

As shown in FIG. 15, a dielectric layer 574 is formed in the first opening 572 and a dielectric layer 584 is formed in the second opening 582. In some implementations, the dielectric layer 574 and the dielectric layer 584 are formed on the sidewalls and bottoms of the first opening 572 and the second opening 582. In some implementations, the dielectric layer 574 and the dielectric layer 584 include silicon oxide or silicon nitride.

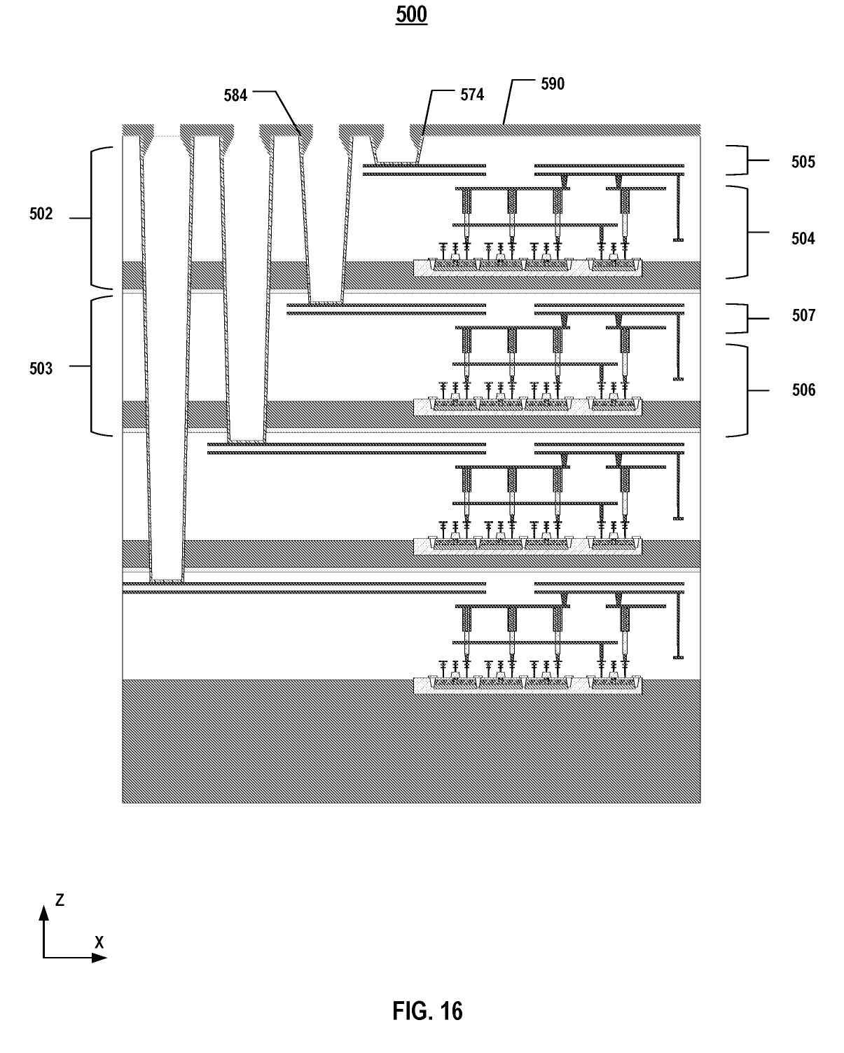

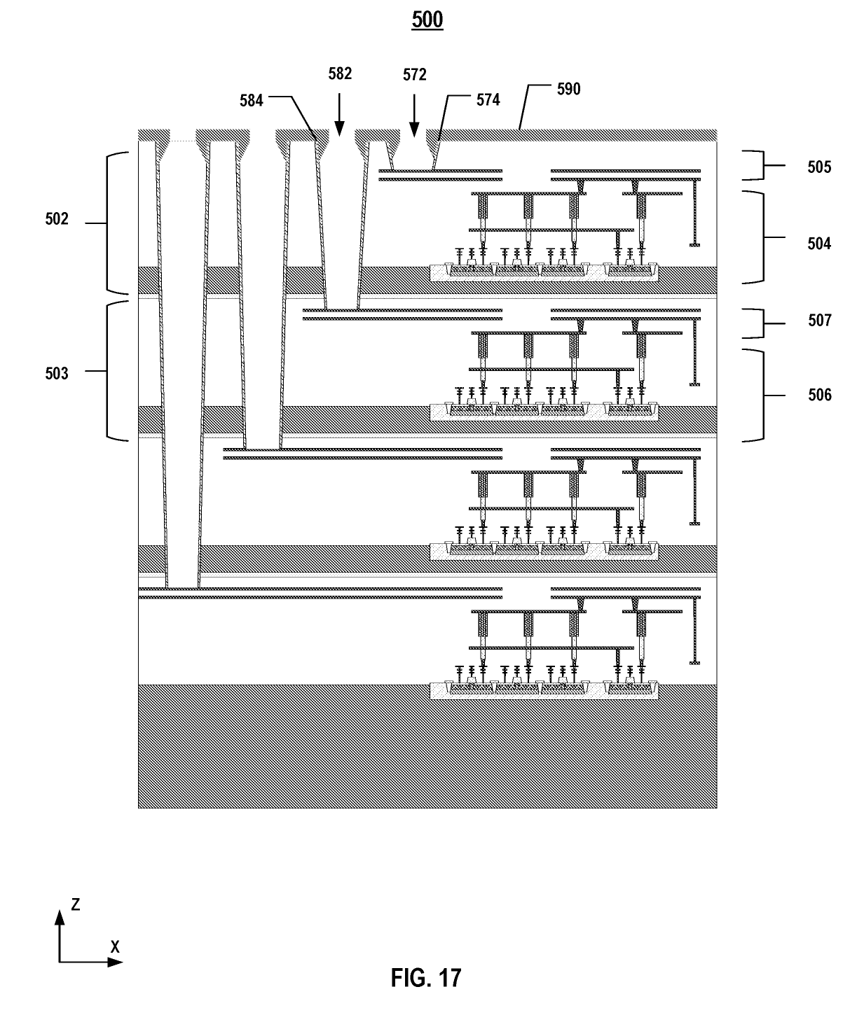

Then, as shown in FIG. 16, a first mask layer 590 is formed on the top surface of the memory device 500 and also covers a portion of the dielectric layer 574 and the dielectric layer 584. In some implementations, the first mask layer 590 is used for protecting the sidewalls of the dielectric layer 574 and the dielectric layer 584 in a later removal operation to remove the bottom of the dielectric layer 574 and the dielectric layer 584. As shown in FIG. 17, the bottoms of the dielectric layer 574 and the dielectric layer 584 are removed by a removal operation, e.g., an etching process, to expose the first conductive line 512 and the third conductive line 522.

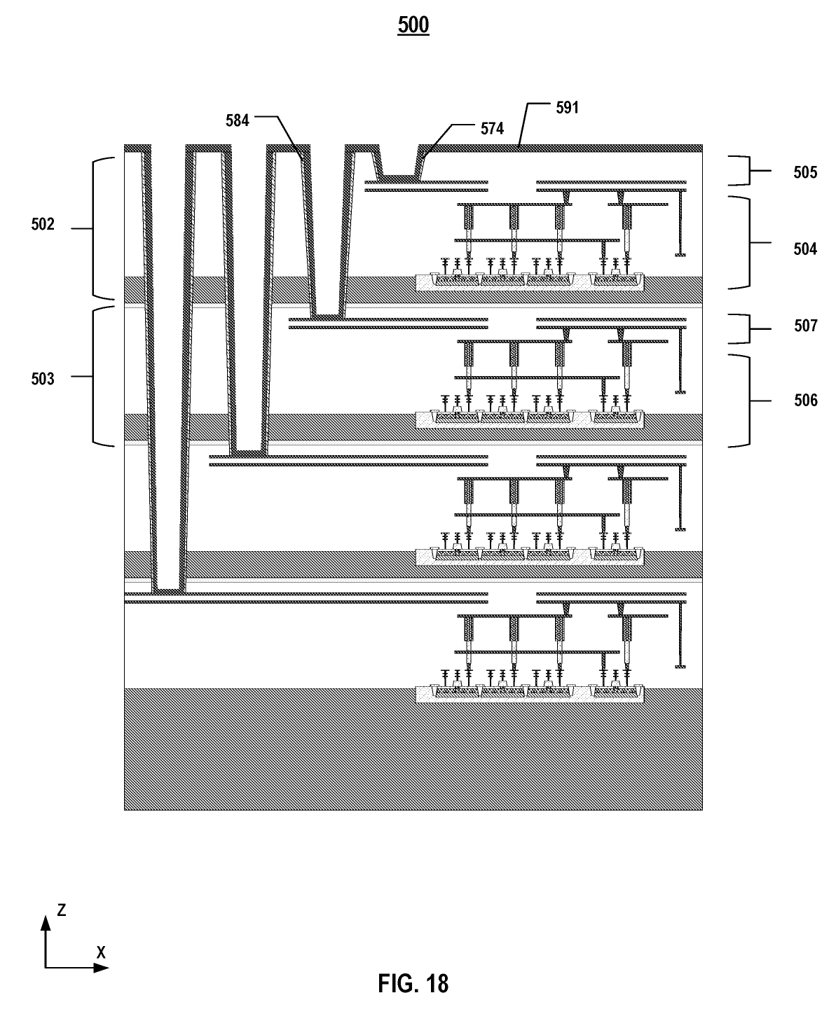

As shown in FIG. 18, the first mask layer 590 is removed and a conductive layer 591 is formed in the first opening 572 and the second opening 582. In some implementations, the conductive layer 591 is formed by metals, e.g., tungsten (W), copper (Cu), aluminum (Al), etc. In some implementations, the conductive layer 591 is in direct contact with the first conductive line 512 and the third conductive line 522. In some implementations, the conductive layer 591 is used as the first outer conductive layer 518 and the second outer conductive layer 528.

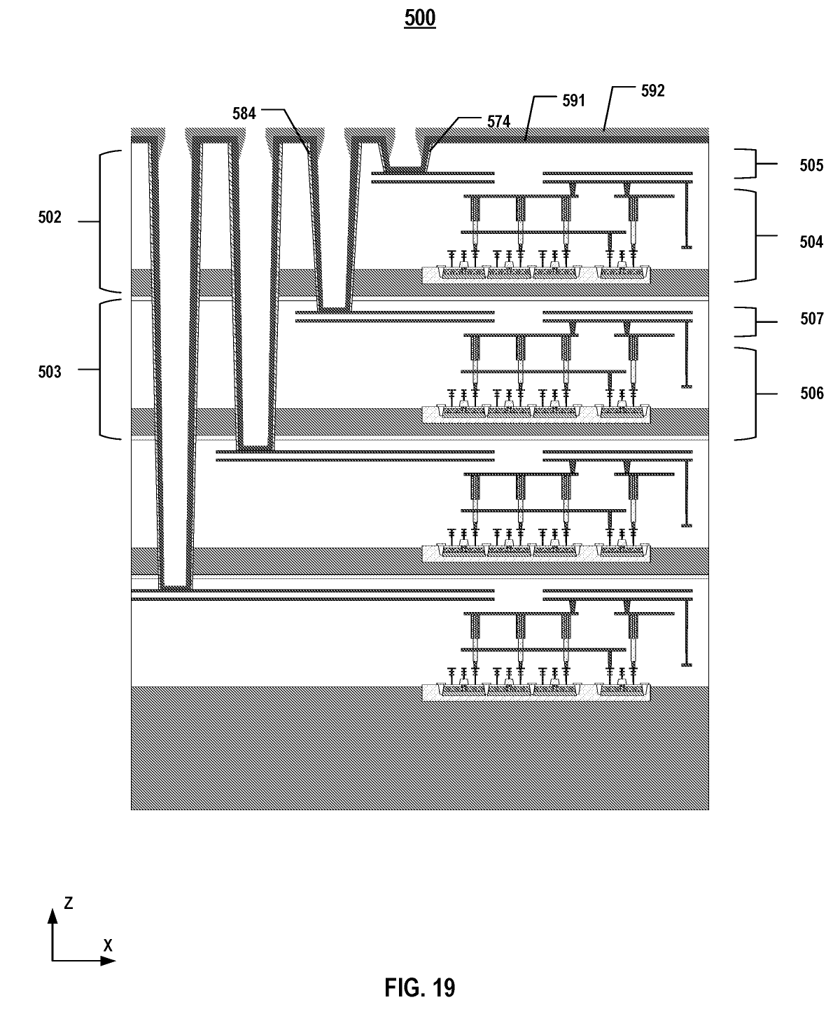

Then, as shown in FIG. 19, a second mask layer 592 is formed on the top surface of the conductive layer 591 and covers a portion of the conductive layer 591 on the sidewalls. In some implementations, the second mask layer 592 is used for protecting the sidewalls of the conductive layer 591 in a later removal operation to remove the bottom of the conductive layer 591 in the first opening 572 and the second opening 582.

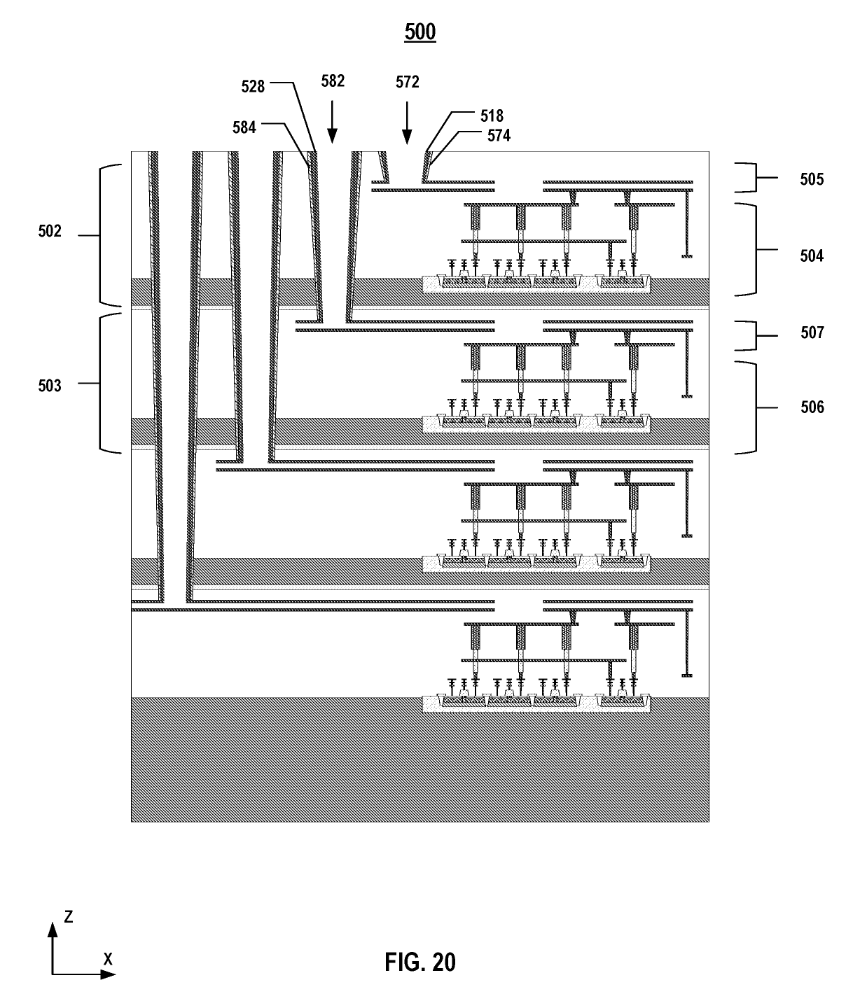

As shown in FIG. 20, a removal operation is performed to remove the bottoms of the conductive layer 591 in the first opening 572 and the second opening 582. In some implementations, the removal operation may remove a portion of the bottoms of the conductive layer 591 in the first opening 572 and the second opening 582. Further, the removal operation also removes the dielectric material between the first conductive line 512 and the second conductive line 514. In some implementations, the removal operation also removes the dielectric material between the third conductive line 522 and the fourth conductive line 524. In other words, after the removal operation shown in FIG. 20, the second conductive line 514 and the fourth conductive line 524 are exposed by the first opening 572 and the second opening 582.

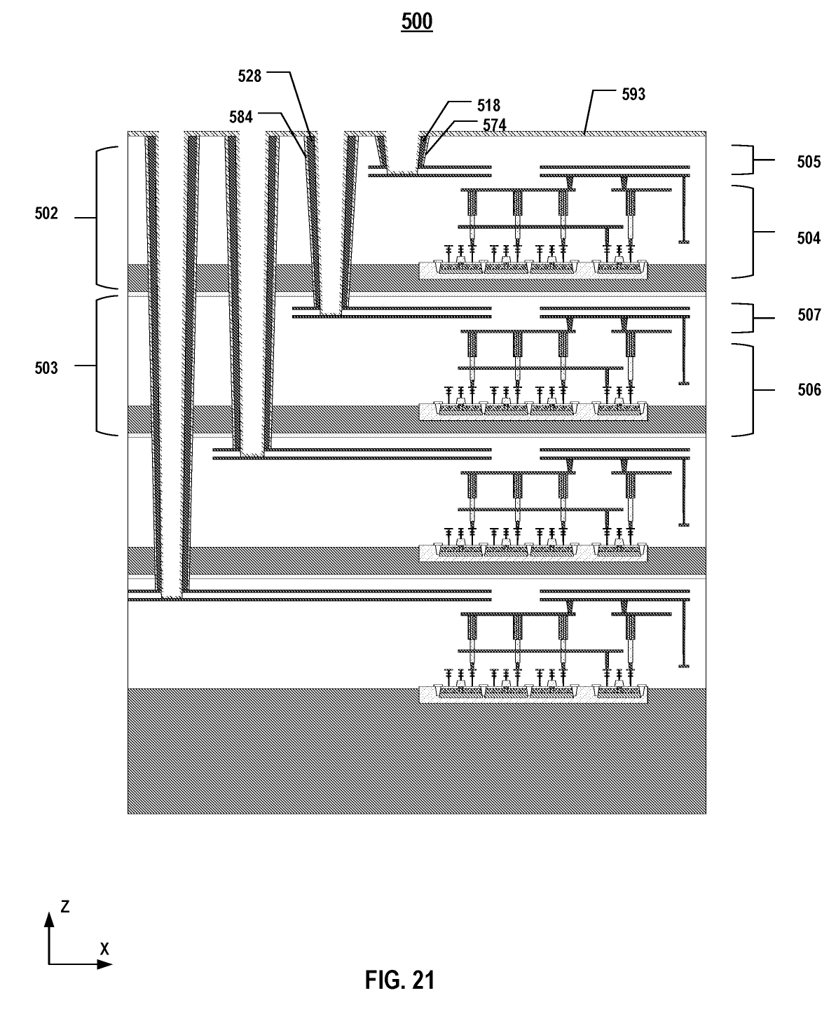

As shown in FIG. 21, the second mask layer 592 is removed and a dielectric layer 593 is formed on the sidewalls and the bottoms of the first opening 572 and the second opening 582. Then, a third mask layer 594 is formed on the top surface of the dielectric layer 593 and also covers a portion of the sidewalls of the dielectric layer 593. In some implementations, the third mask layer 594 is used for protecting the sidewalls of the dielectric layer 593 in a later removal operation to remove the bottom of the dielectric layer 593 in the first opening 572 and the second opening 582.

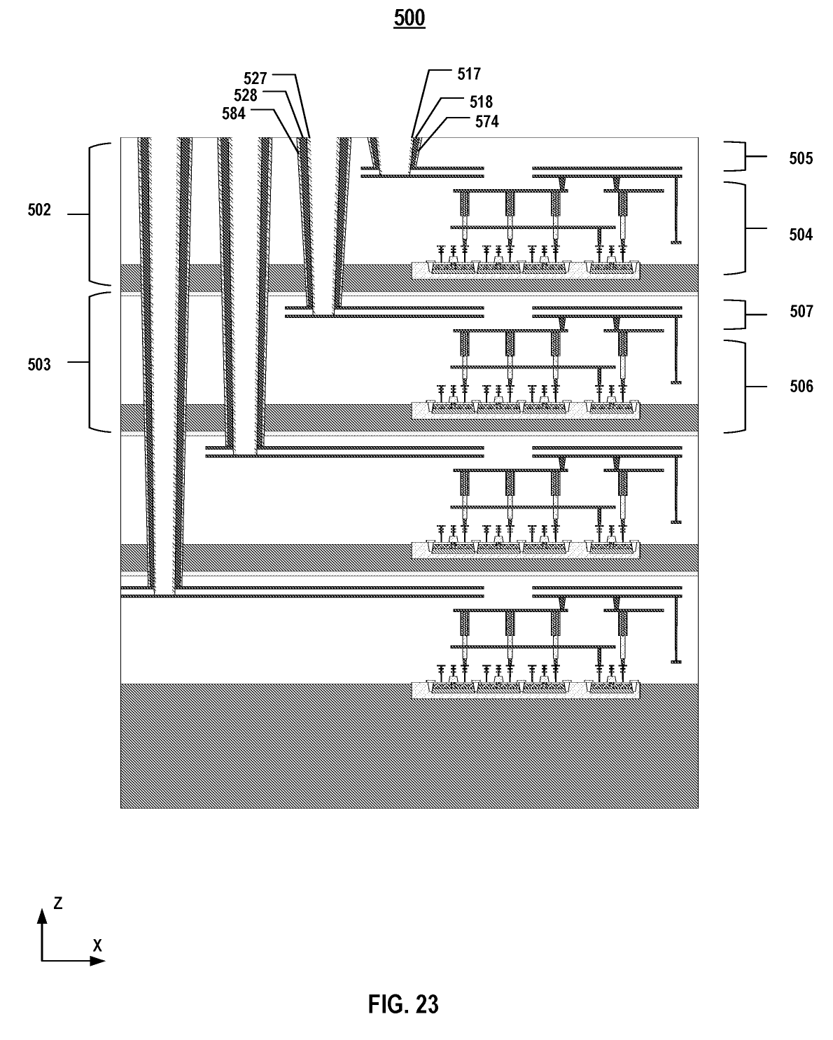

As shown in FIG. 23, a removal operation is performed to remove the bottoms of the dielectric layer 593 in the first opening 572 and the second opening 582 to expose the second conductive line 514 and the fourth conductive line 524.

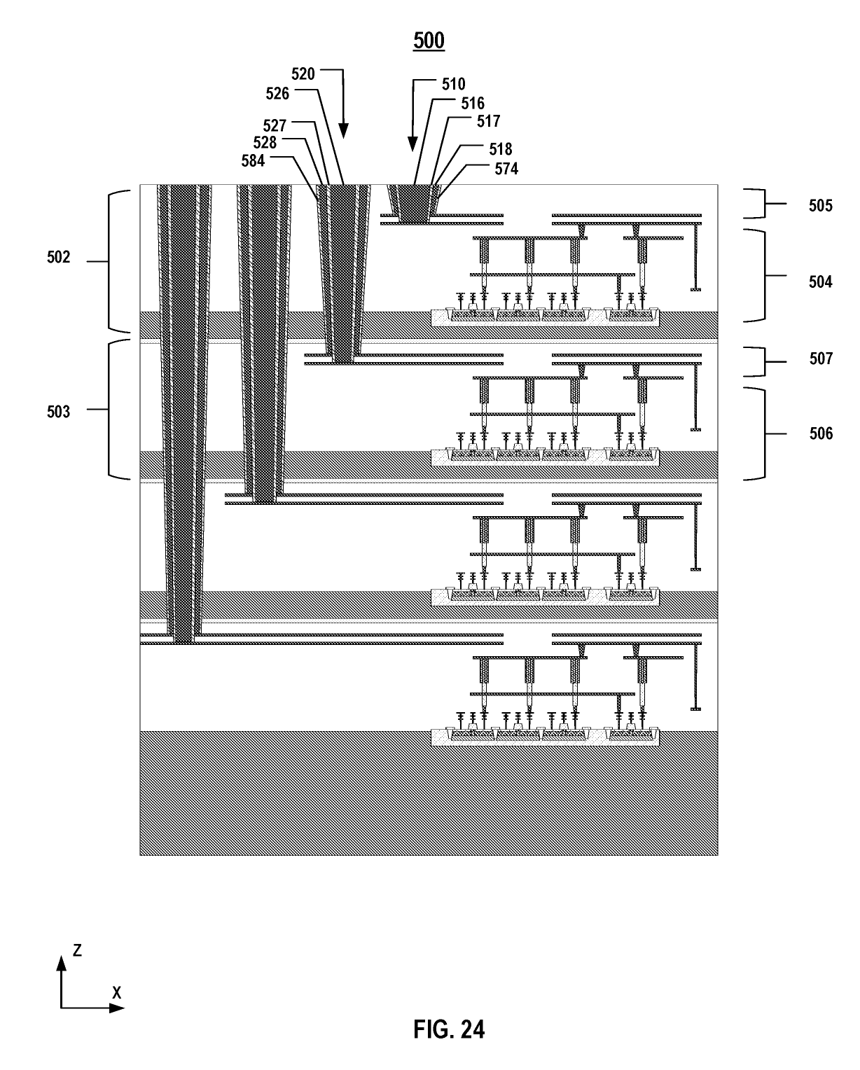

As shown in FIG. 24, the third mask layer 594 is removed and the first inner conductive layer 516 and the second inner conductive layer 526 are formed in the first opening 572 and the second opening 582. In some implementations, the first inner conductive layer 516 is in direct contact with the second conductive line 514. In some implementations, the second inner conductive layer 526 is in direct contact with the fourth conductive line 524. In some implementations, the first inner conductive layer 516 and the second inner conductive layer 526 are formed by metals, e.g., tungsten (W), copper (Cu), aluminum (Al), etc.

In some implementations, the first semiconductor chip 502 and the second semiconductor chip 503 are bonded to the base die 554, and the first inner conductive layer 516 and the first outer conductive layer 518 are coupled to a first differential data driving circuit in the base die 554. In some implementations, the base die 554 and the computing die 556 are bonded to the interposer 558.

In some implementations, the semiconductor chips and the base die 554 are stacked (e.g., sequentially) along the Z-direction. The base die 554 and the computing die 556 are integrated on different positions of the interposer 558 along the X-direction. In some implementations, the memory device 500 may be boned to the base die 554 through a bonding layer. In some implementations, the bonding layer may be the BGA.

In some implementations, the base die 554 includes a control circuitry that is configured to control the memory device 500. The base die 554 is bonded to the interposer 558 through a plurality of bump structures. The base die 554 may be coupled to the computing die 556 through the interposer 558. The interposer 558 may have the conductive terminals and the wirings internally formed in the interposer 558, and the base die 554 may be coupled to the computing die 556 through the conductive terminals and the internal wirings of the interposer 558. It is understood that in practice, the base die 554, the computing die 556, and the interposer 558 can be integrated together using any suitable packaging technology including, for example, Chip-on-Wafer-on-Substrate (CoWoS).

By forming the first contact structure 510 and the second contact structure 520 having the inner conductive layers and the outer conductive layers connected to different metal layers, e.g., the conductive lines 512, 514, 522, and 514, the differential transmission of the signals can be achieved to resist external interference to the signals. In addition, by using the first contact structure 510 and the second contact structure 520 having the inner conductive layers and the outer conductive layers, a higher signal transmission frequency can be achieved without increasing the number of TSVs.

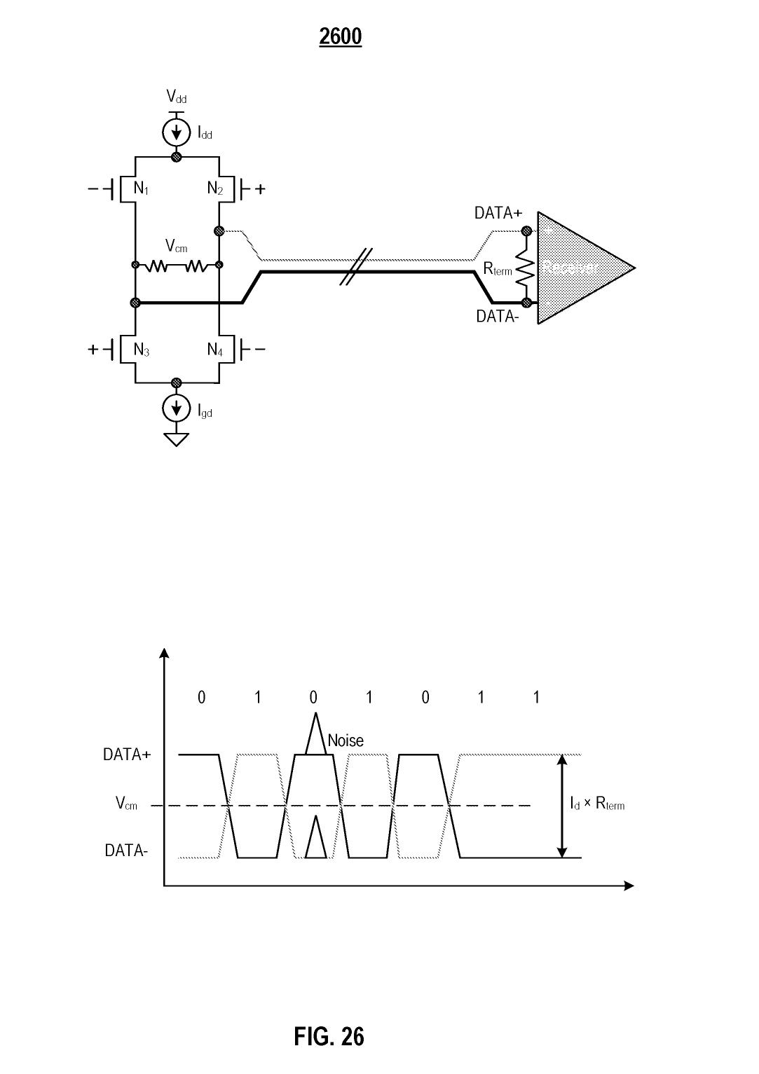

FIG. 26 illustrates a schematic view of a differential circuit 2600, according to some implementations of the present disclosure. The differential circuit 2600 is used for controlling the memory device 500.

A first data signal is transmitted from the first semiconductor chip 502 to a data receiver through the first outer conductive layer 518, and a second data signal is transmitted from the first semiconductor chip 502 to the data receiver through the first inner conductive layer 516. In some implementations, the first data signal and the second data signal are inverse signals, e.g., DATA+ and DATA- in FIG. 26.

In some implementations, the first data signal is transmitted from the first conductive line 512 to the data receiver through the first outer conductive layer 518. In some implementations, the second data signal is transmitted from the second conductive line 514 to the data receiver through the first inner conductive layer 516.

In some implementations, the operating method further includes providing a control signal, by a data butter, to a driving circuit to trigger a differential signal circuit in the driving circuit; and providing the first data signal and the second data signal by the differential signal circuit. In some implementations, the operating method further includes receiving the first data signal and the second data signal by the data received; and differential decoding the first data signal and the second data signal to interpret a voltage difference between the first data signal and the second data signal.

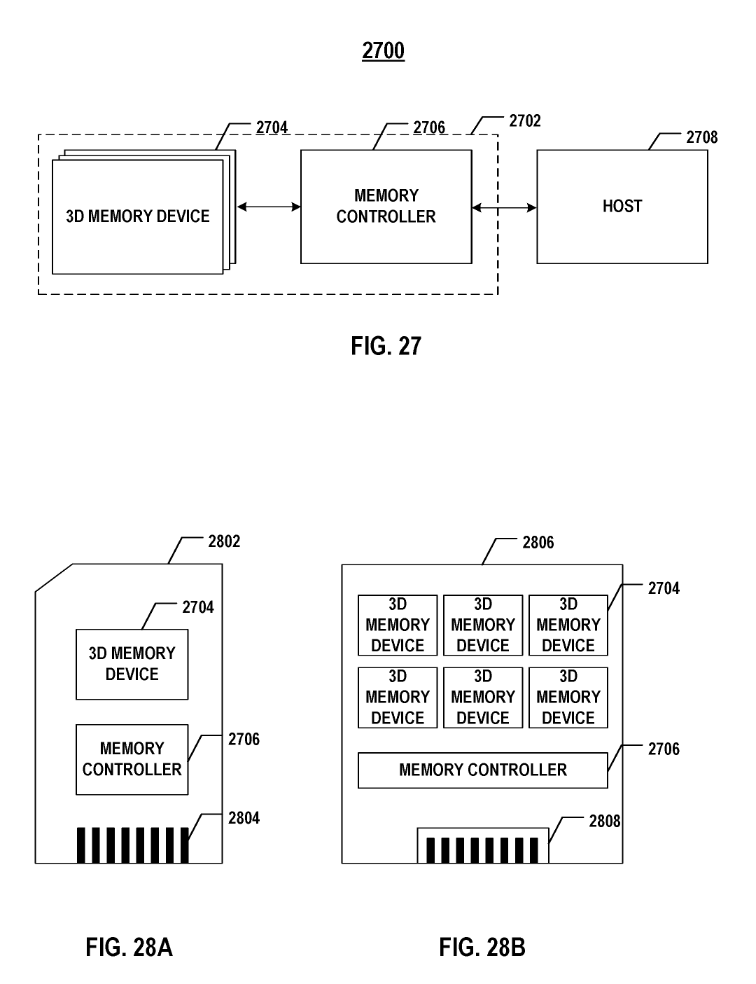

FIG. 27 illustrates a block diagram of a system 2700 having a memory device, according to some aspects of the present disclosure. System 2700 can be a mobile phone, a desktop computer, a laptop computer, a tablet, a vehicle computer, a gaming console, a printer, a positioning device, a wearable electronic device, a smart sensor, a virtual reality (VR) device, an argument reality (AR) device, or any other suitable electronic devices having storage therein. As shown in FIG. 27, system 2700 can include a host 2708 and a memory system 2702 having one or more memory devices 2704 and a memory controller 2706. Host 2708 can be a processor of an electronic device, such as a central processing unit (CPU), or a system-on-chip (SoC), such as an application processor (AP). Host 2708 can be configured to send or receive the data to or from memory devices 2704.

Memory controller 2706 is coupled to memory device 2704 and host 2708 and is configured to control memory device 2704, according to some implementations. In some implementations, memory device 2704 can be the memory device 500 described above. Memory controller 2706 can manage the data stored in memory device 2704 and communicate with host 2708. In some implementations, memory controller 2706 is designed for operating in a low duty-cycle environment like secure digital (SD) cards, compact Flash (CF) cards, universal serial bus (USB) Flash drives, or other media for use in electronic devices, such as personal computers, digital cameras, mobile phones, etc. In some implementations, memory controller 2706 is designed for operating in a high duty-cycle environment SSDs or embedded multi-media-cards (eMMCs) used as data storage for mobile devices, such as smartphones, tablets, laptop computers, etc., and enterprise storage arrays. Memory controller 2706 can be configured to control operations of memory device 2704, such as read, erase, and program operations. In some implementations, memory controller 2706 is configured to control the array of memory cells through the first peripheral circuit and the second peripheral circuit. Memory controller 2706 can also be configured to manage various functions with respect to the data stored or to be stored in memory device 2704 including, but not limited to bad-block management, garbage collection, logical-to-physical address conversion, wear leveling, etc. In some implementations, memory controller 2706 is further configured to process error correction codes (ECCs) with respect to the data read from or written to memory device 2704. Any other suitable functions may be performed by memory controller 2706 as well, for example, formatting memory device 2704. Memory controller 2706 can communicate with an external device (e.g., host 2708) according to a particular communication protocol. For example, memory controller 2706 may communicate with the external device through at least one of various interface protocols, such as a USB protocol, an MMC protocol, a peripheral component interconnection (PCI) protocol, a PCI-express (PCI-E) protocol, an advanced technology attachment (ATA) protocol, a serial-ATA protocol, a parallel-ATA protocol, a small computer small interface (SCSI) protocol, an enhanced small disk interface (ESDI) protocol, an integrated drive electronics (IDE) protocol, a Firewire protocol, etc.

Memory controller 2706 and one or more memory devices 2704 can be integrated into various types of storage devices, for example, be included in the same package, such as a universal Flash storage (UFS) package or an eMMC package. That is, memory system 2702 can be implemented and packaged into different types of end electronic products. In one example as shown in FIG. 28A, memory controller 2706 and a single memory device 2704 may be integrated into a memory card 2802. Memory card 2802 can include a PC card (PCMCIA, personal computer memory card international association), a CF card, a smart media (SM) card, a memory stick, a multimedia card (MMC, RS-MMC, MMCmicro), an SD card (SD, miniSD, microSD, SDHC), a UFS, etc. Memory card 2802 can further include a memory card connector 2804 coupling memory card 2802 with a host (e.g., host 2708 in FIG. 27). In another example as shown in FIG. 28B, memory controller 2706 and multiple memory devices 2704 may be integrated into an SSD 2806. SSD 2806 can further include an SSD connector 2808 coupling SSD 2806 with a host (e.g., host 2708 in FIG. 27). In some implementations, the storage capacity and/or the operation speed of SSD 2806 is greater than those of memory card 2802.

The foregoing description of the specific implementations can be readily modified and/or adapted for various applications. Therefore, such adaptations and modifications are intended to be within the meaning and range of equivalents of the disclosed implementations, based on the teaching and guidance presented herein.

The breadth and scope of the present disclosure should not be limited by any of the above-described exemplary implementations, but should be defined only in accordance with the following claims and their equivalents.

What is claimed is:

1. A memory device, comprising:
a first semiconductor chip comprising a first semiconductor structure and a first interconnection structure;
a second semiconductor chip stacking with the first semiconductor chip along a first direction, the second semiconductor chip comprising a second semiconductor structure and a second interconnection structure; and
a first contact structure extending along the first direction in the first semiconductor chip in contact with the first interconnection structure,
wherein the first contact structure comprises a first inner conductive layer and a first outer conductive layer surrounding the first inner conductive layer, and the first interconnection structure extends along a second direction perpendicular to the first direction.

2. The memory device of claim 1, further comprising:
a second contact structure extending along the first direction in the first semiconductor chip and the second semiconductor chip, and the second contact structure in contact with the second interconnection structure,
wherein the second contact structure comprises a second inner conductive layer and a second outer conductive layer surrounding the second inner conductive layer.

3. The memory device of claim 2, wherein the first inner conductive layer and the first outer conductive layer are arranged along the second direction, and the second inner conductive layer and the second outer conductive layer are arranged along the second direction.

4. The memory device of claim 2, wherein the second contact structure extends along the first direction in contact with the second interconnection structure without contacting the first interconnection structure.

5. The memory device of claim 2, wherein the first contact structure further comprises a first dielectric layer disposed between the first inner conductive layer and the first outer conductive layer, and the second contact structure further comprises a second dielectric layer disposed between the second inner conductive layer and the second outer conductive layer.

6. The memory device of claim 2, wherein a length of the first inner conductive layer along the first direction is greater than a length of the first outer conductive layer along the first direction, and a length of the second inner conductive layer along the first direction is greater than a length of the second outer conductive layer along the first direction.

7. The memory device of claim 2, wherein the first interconnection structure comprises a first conductive line extending along the second direction and a second conductive line extending along the second direction, and the second interconnection structure comprises a third conductive line extending along the second direction and a fourth conductive line extending along the second direction.

8. The memory device of claim 7, wherein the first conductive line is parallel to the second conductive line, and the third conductive line is parallel to the fourth conductive line.

9. The memory device of claim 7, wherein the first outer conductive layer is in contact with the first conductive line, the first inner conductive layer is in contact with the second conductive line, the second outer conductive layer is in contact with the third conductive line, and the second inner conductive layer is in contact with the fourth conductive line.

10. The memory device of claim 9, wherein a width of the first conductive line along a third direction perpendicular to the first direction and the second direction is greater than a width of the second conductive line along the third direction, and a width of the third conductive line along the third direction is greater than a width of the fourth conductive line along the third direction.

11. A method of forming a memory device, comprising:
forming a first semiconductor chip comprising a first semiconductor structure and a first interconnection structure;
forming a second semiconductor chip comprising a second semiconductor structure and a second interconnection structure;
bonding the first semiconductor chip and the second semiconductor chip along a first direction; and
forming a first contact structure comprising a first inner conductive layer and a first outer conductive layer surrounding the first inner conductive layer,
wherein the first contact structure extends along the first direction in the first semiconductor chip in contact with the first interconnection structure, and the first interconnection structure extends along a second direction perpendicular to the first direction.

12. The method of claim 11, further comprising:
forming a second contact structure comprising a second inner conductive layer and a second outer conductive layer surrounding the second inner conductive layer, wherein the second contact structure extends along the first direction in the first semiconductor chip and the second semiconductor chip, and the second contact structure is in contact with the second interconnection structure.

13. The method of claim 11, wherein forming the first semiconductor chip comprising the first semiconductor structure and the first interconnection structure, comprises:
forming the first semiconductor structure on a substrate; and
forming a first conductive line and a second conductive line on the first semiconductor structure,
wherein the first conductive line and the second conductive line extend along the second direction, the second conductive line is located between the first conductive line and the first semiconductor structure along the first direction, and the first conductive line is parallel to the second conductive line.

14. The method of claim 11, wherein forming the first contact structure comprising the first inner conductive layer and the first outer conductive layer surrounding the first inner conductive layer, comprises:
forming a first concentric column composed of the first inner conductive layer and the first outer conductive layer surrounding the first inner conductive layer.

15. The method of claim 12, wherein forming the second contact structure comprising the second inner conductive layer and the second outer conductive layer surrounding the second inner conductive layer, comprises:
forming a second concentric column composed of the second inner conductive layer and the second outer conductive layer surrounding the second inner conductive layer.

16. The method of claim 13, wherein forming the first contact structure comprising the first inner conductive layer and the first outer conductive layer surrounding the first inner conductive layer, comprises:
forming a first opening extending along the first direction in the first semiconductor chip exposing the first interconnection structure;
forming the first outer conductive layer in the first opening;
forming a first dielectric layer on the first outer conductive layer; and
forming the first inner conductive layer on the first dielectric layer.

17. The method of claim 11, wherein bonding the first semiconductor chip and the second semiconductor chip along the first direction, comprises:
bonding the first semiconductor chip and the second semiconductor chip through a third dielectric layer.

18. The method of claim 12, further comprising:
bonding the first semiconductor chip and the second semiconductor chip to a base die, wherein the first inner conductive layer and the first outer conductive layer are coupled to a first differential data driving circuit in the base die, and the second inner conductive layer and the second outer conductive layer are coupled to a second differential data driving circuit in the base die; and
bonding the base die and a computing die to an interposer.

19. An operating method of a memory device, wherein the memory device comprises a first semiconductor chip, a first contact structure extending in the first semiconductor chip, the first contact structure comprises a first inner conductive layer and a first outer conductive layer surrounding the first inner conductive layer, the operating method comprising:
transmitting a first data signal from the first semiconductor chip to a data receiver through the first outer conductive layer; and
transmitting a second data signal from the first semiconductor chip to the data receiver through the first inner conductive layer,
wherein the first data signal and the second data signal are inverse signals.

20. The operating method of claim 19, further comprising:
receiving the first data signal and the second data signal by the data received; and
differential decoding the first data signal and the second data signal to interpret a voltage difference between the first data signal and the second data signal.
